(19) United States
(12) Patent Application Publication
(10) Pub. No.: US 2025/0189892 A1
(43) Pub. Date: Jun. 12, 2025

(54) POLY-O-HYDROXYAMIDES COMPRISING NOVEL INDANE BIS-O-AMINOPHENOLS, PHOTOSENSITIVE COMPOSITIONS, DIELECTRIC FILMS, AND BUFFER COATINGS CONTAINING THE SAME

(71) Applicant: Fujifilm Electronic Materials U.S.A., Inc., N. Kingstown, RI (US)

(72) Inventors: Binod B. De, Attleboro, MA (US); William A. Reinerth, Riverside, RI (US)

(21) Appl. No.: 18/960,672

(22) Filed: Nov. 26, 2024

Related U.S. Application Data
(60) Provisional application No. 63/608,475, filed on Dec. 11, 2023.

(51) Int. Cl. G03F 7/038; G03F 7/004; G03F 7/16; G03F 7/32

(52) U.S. Cl. CPC G03F 7/0387; G03F 7/0045; G03F 7/0382; G03F 7/168; G03F 7/322

(57) ABSTRACT

This disclosure describes poly-o-hydroxyamides containing novel indane bis-o-aminophenols, negative tone photosensitive compositions containing same, and methods and articles for use thereof.

### CROSS-REFERENCE TO RELATED APPLICATION

The present application claims priority to U.S. Provisional Application Ser. No. 63/608,475, filed on Dec. 11, 2023, the contents of which are hereby incorporated by reference in their entirety.

### BACKGROUND OF THE DISCLOSURE

Dielectric material requirements for semiconductor packaging applications are continuously evolving. The trend in electronic packaging continues to move towards faster processing speeds, increased complexity and higher packing density while maintaining a high level of reliability. As electronic packaging technology advances and chips continue to shrink in size, the demand for innovative and high-performance resin compositions is growing.

### SUMMARY OF THE DISCLOSURE

The disclosure provides negative tone photosensitive compositions including polymers comprising at least one indane bis-o-aminophenol compound as a diamine monomer. The negative tone photosensitive compositions described herein meet the exceedingly challenging requirements of the microelectronics industry. In some embodiments, the disclosure provides negative tone photosensitive compositions comprising poly-o-hydroxyamides having at least one indane bis-o-aminophenol compound as a diamine monomer. In certain embodiments, the disclosure provides negative tone photosensitive compositions that include at least one poly-o-hydroxyamide comprising an indane bis-o-aminophenol monomer of Formula Ia:

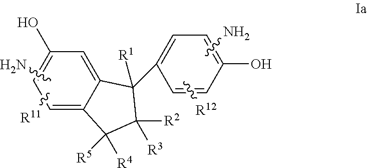

wherein each of R¹, R², R³, R⁴, and R⁵ independently, is a hydrogen atom, a substituted or unsubstituted C₁-C₁₂alkyl, a partially halogen substituted or fully halogen substituted C₁-C₁₂alkyl, a substituted or unsubstituted C₄-C₁₈ cycloalkyl, a substituted or unsubstituted C₆-C₂₂ aryl, or a substituted or unsubstituted C₅-C₂₂ heteroaryl; each of R¹¹ and R¹² is independently a hydrogen atom, a linear or branched C₁-C₄ alkyl, a partially halogen substituted or fully halogen substituted C₁-C₄alkyl, a C₅-C₁₂ cycloalkyl, a C₆-C₁₈ aryl, a C₆-C₁₈ heteroaryl group, a C₁-C₄ alkoxy group or a halogen atom.

Poly-o-hydroxyamides of the present disclosure can be used in photosensitive compositions to provide a negative tone pattern wherein the photosensitive compositions are insoluble in an aqueous alkaline solution after exposure, form a fine pattern, and achieve high resolution.

In some embodiments, the disclosure provides negative tone photosensitive compositions comprising:
a) at least one poly-o-hydroxyamide comprising an indane bis-o-aminophenol monomer of Formula Ia,
(b) at least one photoacid generator;
(c) at least one latent crosslinker; and
(d) at least one solvent.

In some embodiments of the disclosure, there are provided dielectric layers which can be cast from compositions of the disclosure. Dielectric layers of this disclosure can form uniform films which can be developed after exposure to relatively long UV wavelength (e.g., about 365 nm) to form a patterned dielectric film After photolithographic processing, the patterned layer is converted to a heat resistant polybenzoxazole film by application of additional heating, wherein the patterned cured dielectric film can exhibit desirable properties according to one or more reliability tests. Films formed by the photosensitive compositions have good mechanical properties, even when the compositions are cured at low temperature.

Other aspects, embodiments, and advantages follow.

### DETAILED DESCRIPTION OF THE DISCLOSURE

The disclosure provides negative tone photosensitive compositions, as well as related processes, dry films, and dielectric films. In some embodiments, the negative tone photosensitive compositions described herein include (a) at least one polymer comprising at least one indane bis-o-aminophenol compound as a diamine monomer.

In some embodiments there are provided poly-o-hydroxyamides which are suitable for the preparation of photosensitive compositions that meet the exceedingly challenging requirements of the microelectronics industry.

In some embodiments of the disclosure, there are provided negative tone photosensitive composition comprising poly-o-hydroxyamides represented by general Formula (2)

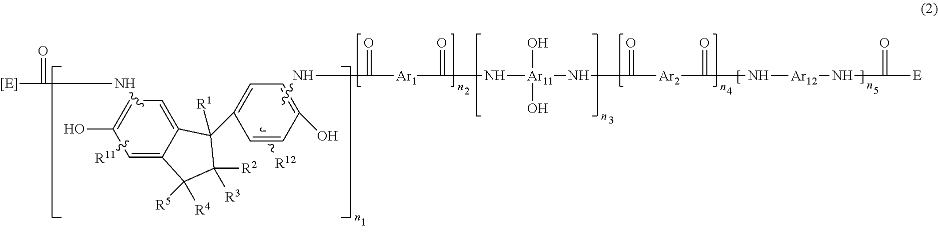

wherein each of R¹, R², R³, R⁴, and R⁵ independently, is a hydrogen atom, a substituted or unsubstituted C₁-C₁₂alkyl, a partially halogen substituted or fully halogen substituted C₁-C₁₂alkyl, a substituted or unsubstituted C₄-C₁₈ cycloalkyl, a substituted or unsubstituted C₆-C₂₂ aryl, or a substituted or unsubstituted C₅-C₂₂ heteroaryl; each of R¹¹ and R¹² is independently a hydrogen atom, a linear or branched C₁-C₄ alkyl, a partially halogen substituted or fully halogen substituted C₁-C₄alkyl, a C₅-C₁₂ cycloalkyl, a C₆-C₁₈ aryl, a C₆-C₁₈ heteroaryl group, a C₁-C₄ alkoxy group or a halogen atom; Ar₁ and Ar₂ are each independently a divalent aromatic, aliphatic, or heterocyclic group, or mixtures thereof; Ar₁₁ and A₁₂ are each independently a divalent aromatic, aliphatic, or heterocyclic group or a siloxane group; E is an end-capping group; n₁ is an integer from 5 to 200; n₃ is an integer from 0 to 200; n₅ is an integer from 0 to 200; n₂ is an integer from 5 to 200 and n₄ is an integer from 0 to 200;

In some embodiments of the disclosure, there are provided negative tone photosensitive composition comprising poly-o-hydroxyamides represented by general Formula (3)

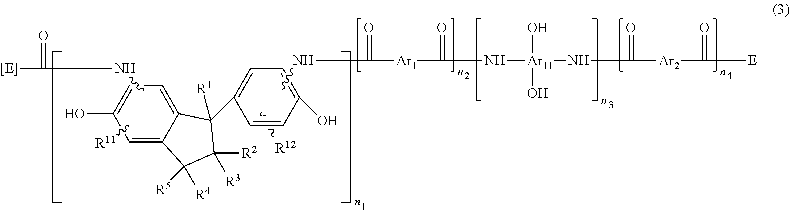

wherein R¹, R², R³, R⁴, R⁵, R¹¹, R¹², Ar₁, Ar₂, Ar₁₁, n¹, n², n³, and n⁴, have the same meaning as described above.

In some embodiments of the disclosure, there are provided negative tone photosensitive compositions comprising poly-o-hydroxyamides represented by general Formula (4)

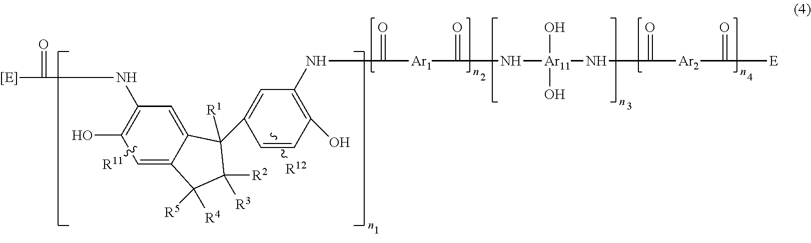

wherein R¹, R², R³, R⁴, R⁵, R¹¹, R¹², Ar₁, Ar₂, Ar₁₁, n¹, n², n³, and n⁴ have the same meaning as described above.

As used herein, “end-capping group” refers to a reaction product of amino end groups of poly-o-hydroxyamides with a monoanhydride compound. Monoanhydride compounds, when added to the polymerization system, facilitate termination of a poly-o-hydroxyamide chain, thereby limiting polymer chain growth.

In some embodiments, Ar₁ and Ar₂ include the following moieties:

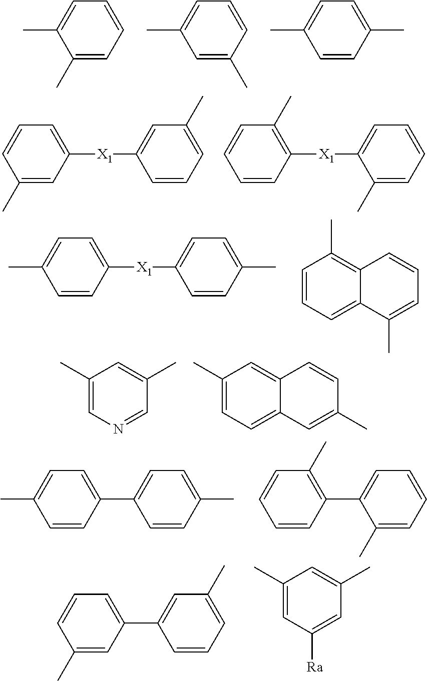

in which X₁ is —C(O)—C(O)—, —C(O)O—, a C₅-C₇ cyclic aliphatic group, fluorenyl group, —O—X₃—O, —O—C(O)—X₃—C(O)—O—, —C(O)—O—X₃—O—C(O)— or —(CH₂)ₘ—Si(Z)₂—O—Si(Z)₂—(CH₂)ₘ— where X₃ is a unsubstituted or substituted phenyl, diphenyl sulfone, isopropylidene diphenyl, hexafluoroisopropylidene diphenyl and Z is a H or a C₁-C₆ alkyl group and m is an integer from 1 to 6, Ra is each independently a hydrogen atom, an alkoxy, a fluoroalkoxy, a cycloalkyl, a cycloalkoxy, a cycloalkylsulfonyl, an aryloxy, an alkylaryloxy, an arylsulfonyl, or an alkylarylsulfonyl group. In some embodiments, the poly-o-hydroxyamide can contain one or more different Ar₁ and Ar₂ groups.

In some embodiments, Ar₁₁ include the following moieties:

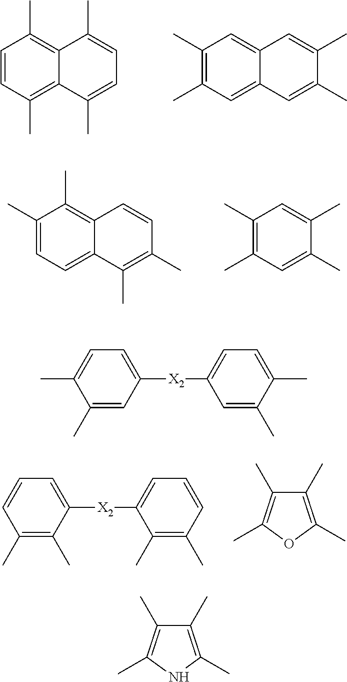

in which X₂ is —O—, —S—, —C(CF₃)₂—, —C(CH₃)₂—, —CH₂—, —SO₂—, —NHCO—, —C(O)—, —C(O)—C(O)—, —C(O)O—, a C₅-C₇ cyclic aliphatic group, fluorenyl group, —O—X₄—O, —O—C(O)—X₄—C(O)—O—, —C(O)—O—X₄—O—C(O)— or —(CH₂)ₘ—Si(Z)₂—O—Si(Z)₂—(CH₂)ₘ—, X₄ is a unsubstituted or substituted phenyl, diphenyl sulfone, isopropylidene diphenyl, hexafluoroisopropylidene diphenyl and Z and m have the same meaning as described above.

Dicarboxylic acid chlorides of the disclosure include, for example, aromatic dicarboxylic acid chlorides such as isophthalic acid chloride, terephthalic acid chloride, 4,4′-hexafluoroisopropylidenedibenzoic acid chloride, 4,4′-biphenyldicarboxylic acid chloric, 4,4′-dicarboxydiphenyl ether chloride, 4,4′-dicarboxytetraphenylsilane chloride, bis(4-carboxyphenyl) sulfone chloride, 2,2-bis(p-carboxyphenyl)propane chloride, 5-tert-butylisophthalic acid chloride, 5-bromoisophthalic acid chloride, 5-fluoroisophthalic acid chloride, 5-chloroisophthalic acid chloride, 2,6-naphthalenedicarboxylic acid chloride, etc.; aliphatic dicarboxylic acid chlorides such as 1,2-cyclobutanedicarboxylic acid chloride, 1,4-cyclohexanedicarboxylic acid chloride, 1,3-cyclopentanedicarboxylic acid chloride, malonic acid chloride, succinic acid chloride adipic acid chloride, sebacoyl chloride, etc Examples of such diacid chlorides are disclosed in, e.g., U.S. Pat. Nos. 6,143,467 and 7,803,510 wherein, the entire contents of which are hereby incorporated by reference. Any of these dicarboxylic acid chlorides can be used individually or in combination in any suitable ratio to form a poly-o-hydroxyamide described herein.

Examples of indane bis-o-aminophenol compound (Ia) include, but are not limited to:

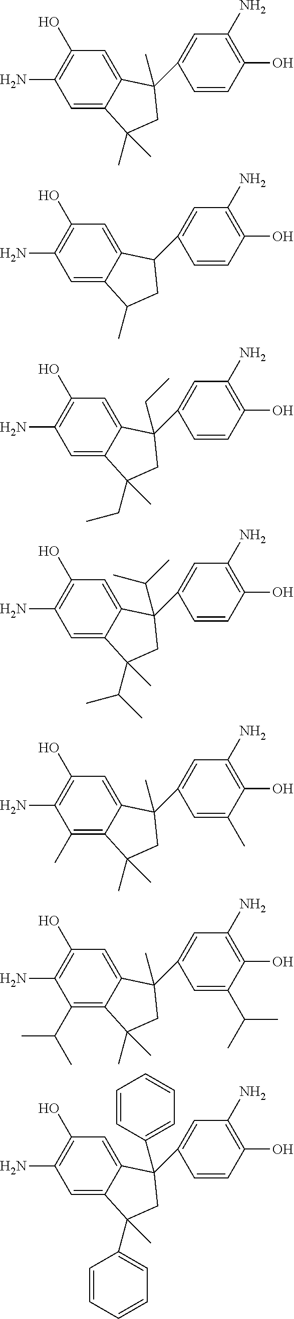

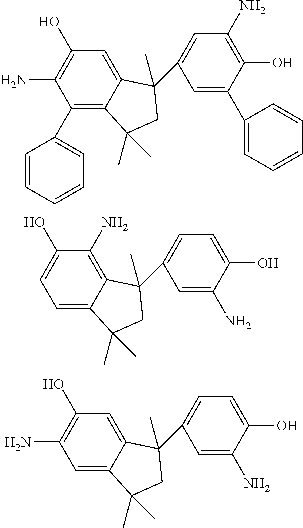

Additional monomers contemplate for use include bis-o-hydroxyamines, such as, for example, 3,3′-diamino-4,4′-dihydroxybiphenyl, 4,4′-diamino-3,3′-dihydroxybiphenyl, bis(3-amino-4-hydroxyphenyl) propane, bis(4-amino-3-hydroxyphenyl) propane, bis(3-amino-4-hydroxyphenyl) sulfone, bis(4-amino-3-hydroxyphenyl) sulfone, bis(3-amino-4-hydroxyphenyl) hexafluoropropane, bis(4-amino-3-hydroxyphenyl) hexafluoropropane, etc. Further examples of such bis-o-hydroxyamines are disclosed in, e.g., U.S. Pat. Nos. 6,143,467; 7,803,510, the entire contents of which are hereby incorporated by reference. Any of these bis-o-hydroxyamines can be used individually or in combination in any suitable ratio to form a poly-o-hydroxyamide described herein.

Examples of suitable diamines containing an Ar₁₂ structure that can be used to prepare a poly-o-hydroxyamide polymer of structure (2) include, but are not limited to, 1-(4-aminophenyl)-1,3,3-trimethylindan-5-amine (alternative names including 4,4′-[1,4-phenylene-bis(1-methylethylidene)]bisaniline, 1-(4-aminophenyl)-1,3,3-trimethyl-2H-inden-5-amine, 1-(4-aminophenyl)-1,3,3-trimethyl-indan-5-amine, and [1-(4-aminophenyl)-1,3,3-trimethyl-indan-5-yl]amine), 1-(4-aminophenyl)-2,3-dihydro-1,3,3-trimethyl-1H-inden-5-amine, 5-amino-6-methyl-1-(3′-amino-4′-methylphenyl)-1,3,3-trimethylindan, 4-amino-6-methyl-1-(3′-amino-4′-methylphenyl)-1,3,3-trimethylindan, 5,7-diamino-1,1-dimethylindan, 4,7-diamino-1,1-dimethylindan, 5,7-diamino-1,1,4-trimethylindan, 5,7-diamino-1,1,6-trimethylindan, 5,7-diamino-1,1-dimethyl-4-ethylindan, p-phenylenediamine, m-phenylenediamine, o-phenylenediamine, 3-methyl-1,2-benzene-diamine, 1,2-diaminoethane, 1,3-diaminopropane, 1,4-diaminobutane, 1,5-diaminopentane, 1,6-diaminohexane, 1,7-diaminoheptane, 1,8-diaminooctane, 1,9-diaminononane, 1,10-diaminodecane, 1,2-diaminocyclohexane, 1,4-diaminocyclohexane, 1,3-cyclohexanebis(methylamine), 5-amino-1,3,3-trimethyl cyclohexanemethanamine, 2,5-diaminobenzotrifluoride, 3,5-diaminobenzotrifluoride, 1,3-diamino-2,4,5,6-tetrafluorobenzene, 4,4′-oxydianiline, 3,4′-oxydianiline, 3,3′-oxydianiline, 3,3′-diaminodiphenylsulfone, 4,4′-diaminodiphenylsulfone, 4,4′-isopropylidenedianiline, 4,4′-diaminodiphenylmethane, 2,2-bis(4-aminophenyl)propane, 4,4′-diaminodiphenyl propane, 4,4′-diaminodiphenyl sulfide, 4,4′-diaminodiphenylsulfone, 4-aminophenyl-3-aminobenzoate, 2,2′-dimethyl-4,4′-diaminobiphenyl, 3,3′-dimethyl-4,4′-diaminobiphenyl, 2,2′-bis(trifluoromethyl) benzidine, 3,3′-bis(trifluoromethyl) benzidine, 2,2-bis[4-(4-aminophenoxyphenyl)]hexafluoropropane, 2,2-bis(3-amino-4-methylphenyl)-hexafluoropropane, 2,2-bis(3-aminophenyl)-1,1,1,3,3,3-hexafluoropropane, 1,3-bis-(4-aminophenoxy)benzene, 1,3-bis-(3-aminophenoxy)benzene, 1,4-bis-(4-aminophenoxy)benzene, 1,4-bis-(3-aminophenoxy)benzene, 1-(4-aminophenoxy)-3-(3-aminophenoxy)benzene, 2,2′-bis-(4-phenoxyaniline)isopropylidene, bis(p-beta-amino-t-butylphenyl)ether, p-bis-2-(2-methyl-4-aminopentyl)benzene, p-bis(1,1-dimethyl-5-aminopentyl)benzene, 3,3′-dimethyl-4,4′-diaminobiphenyl, 4,4′-diaminobenzophenone, 3′-dichlorobenzidine, 2,2-bis[4-(4-aminophenoxy)phenyl]propane, 4,4′-[1,3-phenylenebis(1-methyl-ethylidene)]bisaniline, 4,4′-[1,4-phenylenebis(1-methyl-ethylidene)]bisaniline, 2,2-bis[4-(4-aminophenoxy) phenyl]sulfone, 2,2-bis[4-(3-aminophenoxy)benzene], 1,4-bis(4-aminophenoxy)benzene, 1,3-bis(4-aminophenoxy)benzene, 1,3′-bis(3-aminophenoxy)benzene 4,4′-diamino-2,2′-bis(trifluoromethyl)biphenyl, H-fluorene-2,6-diamine, 4,4′-methylenebis(2,6-diethylaniline), 4,4′-methylenebis(2,6-dimethylaniline), 4,4′-methylenebis(2,6-diisopropylaniline), 4,4′-ethylenebis(2,6-dipropylaniline), 4,4′-methylenebis(2,6-di tert-butylaniline), 3,5-diaminobenzoic acid, 3,4-diaminobenzoic acid, bis(aminopropyl)tetramethyldisiloxane (BATMS), bis(aminopropyl)tetraphenyldisiloxane, bis(4-aminophenoxy)dimethylsilane and the like. Any of these diamines can be used individually or in combination in any suitable ratio to form a poly-o-hydroxyamide described herein.

The poly-o-hydroxyamide Structure (2a) may be synthesized by numerous synthetic procedure where variations of those procedures are known to those skilled in the art.

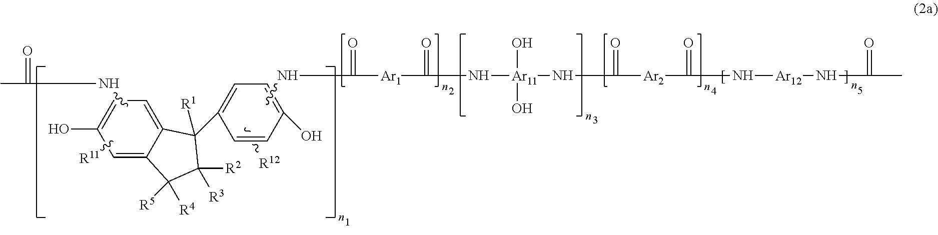

wherein R¹, R², R³, R⁴, R⁵, R¹¹, R¹², Ar₁, Ar₂, A₁₁, Ar₁₂, n₁, n₂, n₃, n₄ and n₅ have the same meaning as described above.

In general, the synthetic procedure brings one or more bis-o-hydroxyamine in contact with one or more diacid chloride in the presence of a solvent and optionally a base or mixture thereof suitable to dissolve the monomers, and preferably the resultant poly-o-hydroxyamide. Examples of suitable base include, but are not limited to, pyridine, triethylamine, tripropylamine, tributylamine, dicyclohexylmethylamine, 2,6-lutidine, 3,5-lutidine, picoline, 4-dimethylaminopyridine (DMAP) and the like. If used, the basic catalyst employed can be the same as or different from the basic catalyst employed in the end-capping reaction.

In some embodiments, to prepare a poly-o-hydroxyamide, the bis-o-hydroxyamine component and diacid chloride component are charged into a reaction vessel by a method of gradually charging one of the components in the form of solid or solution into a solution of the other component (complete dissolution of all materials might not occur) or a method of charging both the components at the same time. The molar ratio of bis-o-hydroxyamine component(s) to diacid chloride component(s) is preferably from between 1.01 to 1.50. More preferably, a molar ratio of diamine to diacid chloride of about 1.05 to 1.30 is employed. Generally, the reaction is carried out at about −15° C. to about 50° C. for about 1 to about 48 hours. Note that when the molar ratio of bis-o-hydroxyamine component(s) to diacid chloride component(s) is greater than 1.00, the resulting species is an amino-terminated poly-o-hydroxyamide, which can be further reacted with an end-capping monomer to form an end-capped polymer.

Suitable polymerization solvents useful in the present invention include, but are not limited to, N-methyl-2-pyrrolidone, N,N-dimethylformamide, dimethylsulfoxide, gamma-butyrolactone, N, N-dimethylacetamide, tetramethylene sulfone, p-chlorophenol, m-cresol, diethyleneglycol methyl ether, methyl-3-methoxyproprionate, ethyl-3-ethoxypropionate, cyclohexanone, propylene glycol monomethyl ether acetate, and 2-chloro-4-hydroxytoluene. These solvents may be used singly or in combination of two or more. Of these solvents, preferred are N-methyl-2-pyrrolidone, gamma-butyrolactone and N, N-dimethylacetamide, with N-methyl-2-pyrrolidone being more preferred. In some embodiments, a poor solvent for the poly-o-hydroxyamide may be used in combination with these solvents in such an amount to not allow the poly-o-hydroxyamide to precipitate. Examples of such a poor solvent include hexane, heptane, benzene, toluene, xylene, chlorobenzene and o-dichlorobenzene. The amount of the poor solvent to be used is preferably 50 percent by weight or less (inclusive of zero) based on the total amount of the solvents. The poly-o-hydroxyamide thus produced may be isolated by precipitation into a non-solvent or a poor solvent and collected by filtration.

The second step of the synthetic process towards the polymer of Structure (2a) mentioned above is to end-cap the poly-o-hydroxyamide of Structure (2).

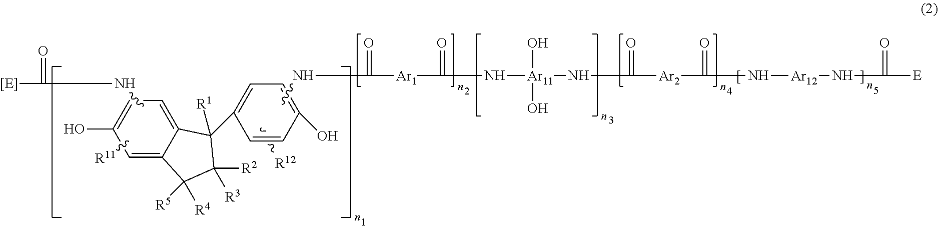

wherein R¹, R², R³, R⁴, R⁵, R¹¹, R¹², Ar₁, Ar₂, A₁₁, Ar₁₂, n₁, n₂, n₃, n₄, n₅ and E have the same meaning as described above.

In some embodiments, the second step can be carried out by reacting an amino-terminated poly-o-hydroxyamide with a monoanhydride to yield an end-capped poly-o-hydroxyamide of Structure (2) In some embodiments, the end-capped poly-o-hydroxyamide thus formed can be used for further reaction without isolation. Monoanhydrides contemplate for use in this aspect of the disclosure include, for example, aliphatic acid anhydrides such as acetic anhydride, trifluoroacetic anhydride, pivalic anhydride, or cyclic anhydrides such as 1,1-cyclopentanediacetic anhydride, succinic anhydride, maleic anhydride, exo-3,6-epoxy-1,2,3,6-tetrahydrophthalic anhydride, cis-1,2-cyclohexanedicarboxylic anhydride, cis-4-cyclohexene-1,2-dicarboxylic anhydride, 5-norbornene-2,3-dicarboxylic anhydride, bicyclo[2.2.1]hept-5-ene-2,3-dicarboxylic anhydride and the like. Further examples of end-capping groups are disclosed in, e.g., U.S. Pat. No. 9,695,284, the entire contents of which are hereby incorporated by reference.

In some embodiments, the second step can be carried out by reacting an amino-terminated poly-o-hydroxyamide and unreacted diamine monomers with a monoanhydride to yield an end-capped poly-o-hydroxyamide and adducts wherein an amine value of poly-o-hydroxyamide polymer precursor is about 0.0010 to 0.0300 mmol/g. When the amine value is higher than these numerical values, the amine group will interfere with the photoacid generated by exposure of light to photoacid generators.

The weight average molecular weight (Mw) of the poly-o-hydroxyamide can be determined by such standard methods as membrane osmometry or gel permeation chromatography as described, for example, in Jan Rabek, Experimental Methods in Polymer Chemistry, John Wiley & Sons, New York, 1983.

Suitable weight average molecular weight (Mw) ranges for the poly-o-hydroxyamide of the disclosure range from about 1,000 g/mol to about 80,000 g/mol. Preferred molecular weight ranges may depend on the particular product application, solvent employed, and method of applying to the underlying substrate. For example, suitable weight average molecular weight values for coating applications can be at least about 1,000 g/mol (e.g., at least about 9,000 g/mol, at least about 12,000 g/mol, at least about 15,000 g/mol, at least about 20,000 g/mol, at least about 25,000 g/mol, or at least about 35,000 g/mol) and/or can be at most about 80,000 g/mol (e.g., at most about 60,000 g/mol, at most about 50,000 g/mol, at most about 40,000 g/mol.

In this disclosure, when the term “solvent(s)” is used, if not specifically stated, it refers to either a single organic solvent or a combination of two or more organic solvents. The purification or isolation of poly-o-hydroxyamide may be accomplished by numerous procedures of those procedures known to those skilled in the art. The solution isolation procedure of poly-o-hydroxyamide polymer is one of the efficient, environmentally friendly process to produce poly-o-hydroxyamide polymers having enhanced purity.

The purification process can include (a) providing an organic solution containing a poly-o-hydroxyamide in at least one polar, aprotic polymerization solvent; (b) adding at least one purification solvent to the organic solution to form a diluted organic solution, the at least one purification solvent is less polar than the at least one polymerization solvent and has a lower water solubility than the at least one polymerization solvent at 25° C.; (c) washing the diluted organic solution with acidified aqueous solution to obtain a washed organic solution; (d) removing at least a portion of the at least one purification solvent in the washed organic solution to obtain a solution containing a purified poly-o-hydroxyamide.

Without wishing to be bound by theory, it is believed that the two functions of the purification solvent(s) are to (1) maintain the poly-o-hydroxyamide polymer in solution and (2) form a biphasic mixture with water and/or an aqueous solution containing an additive. In the context of this disclosure, biphasic mixture refers to a mixture containing two distinct and separate phases (e.g., two distinct liquid phases).

In some embodiments, the purification solvent(s) can include an ester, an ether, a ketone, a hydrocarbon optionally substituted by at least one chloride. Examples of suitable purification solvent(s) include, but are not limited to, methyl acetate, ethyl acetate, n-propyl acetate, isopropyl acetate, n-butyl acetate, isobutyl acetate, sec-butyl acetate, cyclohexyl acetate, ethyl lactate, propylene glycol monomethyl ether acetate (PGMEA), tetrahydrofurfuryl acetate, propyl formate, butyl formate, isobutyl formate, pentyl formate, epsilon-caprolactone, diethyl ether, dipropyl ether, dibutyl ether, dicyclohexyl ether, cyclopentyl methyl ether, methyl tert-butyl ether, ethyl tert-butyl ether, anisole, phenyl ethyl ether, diphenyl ether, 1,2-dimethoxypropane, 1,2-dimethoxyethane, 2-butanone, 2-pentanone, 3-pentanone, methyl isobutyl ketone, ethyl isobutyl ketone, methyl isopropyl ketone, cyclopentanone, cyclohexanone, acetophenone, isophorone, mesityl oxide, benzene, toluene, xylene, ethyl benzene, chlorobenzene, 1,2-dichlorobenzene, α,α,α-trifluorotoluene, pentane, hexane, heptane, octane, cyclohexane, methylcyclohexane, cyclohexene, and mixtures thereof.

Depending on the solubility characteristics of the poly-o-hydroxyamide polymer, the purification solvent(s) may be used as the sole solvent(s) in the dilution/purification step. However, in some embodiments, in addition to the purification solvent(s), a purification co-solvent(s) may be employed. Purification co-solvents are organic solvents that have a higher (e.g., significantly higher) solubility in water at 25° C. than the purification solvent(s). In general, a purification co-solvent(s) is not used alone but is used in combination with one or more purification solvent(s). In some embodiments, the purification solvents can be water immiscible solvents.

Examples of suitable purification co-solvents include, but are not limited to, acetone, gamma-butyrolactone (GBL), furan, tetrahydrofuran, methyl tetrahydrofuran, tetrahydrofurfuryl methyl ether, 1,4-dioxane, and mixtures thereof. In some embodiments, the purification co-solvents can be water miscible solvents.

When an aqueous solution containing an additive is employed in this step, this solution can contain an acid, a base, or additional components, such as chelating agents, in a sufficient concentration to enhance the purity of the poly-o-hydroxyamide polymer by removal of impurities (e.g., polymerization by-products). The concentration of the acid, the base, or other additives in this aqueous solution may range from at least about 0.1 wt % (e.g. at least about 0.3 wt %, at least about 0.5 wt %, or at least about 1 wt %) to at most about 10 wt % (e.g. at most about 8 wt %, at most about 7 wt %, or at most about 5 wt %).

In some embodiments, the washing step can include adding water or an aqueous solution to the diluted organic solution obtained in the dilution step above. In such embodiments, the washing step can include forming a mixture having an organic phase and an aqueous phase (e.g., by allowing the organic phase and the aqueous phase to separate from each other). The washing step can further include removing the aqueous phase. In general, washing the diluted solution can substantially remove the at least one polymerization solvent or another impurity in the diluted organic solution.

In order to improve the effectiveness of the washing step, the diluted organic solution containing a poly-o-hydroxyamide polymer and the aqueous washing medium (e.g., water or an aqueous solution) can be mixed by agitation. This agitation may take the form of stirring, shaking, inverting or any other method which permits effective mixing of the organic and aqueous phases.

Following mixing, the mixture can be allowed to stand undisturbed until two distinct and separate phases are formed. Upon the formation of distinct and separate phases, the aqueous phase can be removed and discarded to remove impurities (e.g., a polymerization solvent). This may be repeated any number of times to achieve the desired polymer purity. In some embodiments, the number of aqueous washes is from one to five (i.e., one, two, three, four or five).

A wide range of agitation rate, time, temperature, and separation conditions may be employed. Without wishing to be bound by theory, it is believed that an essential aspect of this step is to ensure sufficient mixing of the mixtures to extract significant amounts of the polymerization solvent(s) and other impurities into the aqueous phase followed by phase separation. These conditions may vary depending on the vessel employed for the mixing and separation. In some embodiments, the agitation time is from about 1 minute to about 24 hours (e.g., from about 10 minutes to about 6 hours). In some embodiments, the agitation temperature is from about 10° C. to about 40° C. (e.g., from about 15° C. to about 30° C.). In some embodiments, the separation time is from about 10 minutes to about 24 hours (e.g., from about 15 minutes to about 12 hours). In some embodiments, the separation temperature is from about 10° C. to about 40° C. (e.g., from about 15° C. to about 30° C.).

In some embodiments, when a poly-o-hydroxyamide polymer is being formed and purified, the amount of residual polymerization solvent(s) remaining after the final aqueous washing is at most about 1 wt % (e.g., at most about 0.5 wt %) of the weight of the poly-o-hydroxyamide polymer.

After the organic solution containing a poly-o-hydroxyamide polymer is washed by an aqueous medium (e.g., water), at least a portion (e.g., substantially all) of the purification solvent(s) in the organic solution can be removed or exchanged for at least one isolation solvent(s) to obtain a solution containing a purified poly-o-hydroxyamide polymer (i.e., a purified polymer solution).

In some embodiments, a solution containing a purified poly-o-hydroxyamide polymer (i.e., a purified polymer solution) is treated with ion exchange resin (acidic, basic or mixture of acidic and basic ion exchange resin) to remove trace amount acid or base from purified polymer solution. In certain embodiments, the ion exchanged purified poly-o-hydroxyamide solution is filtered through a filter media (pad, cartridge) to remove if any gel present in the polymer solution.

In some embodiments, at least a portion (e.g., substantially all) of the purification solvent(s) (and essentially all residual water) in the purified polymer solution can be solvent exchanged for an isolation solvent(s). In some embodiments, the isolation solvent(s) is a solvent or combination of two or more solvents whose boiling point is equal to or greater than the purification solvent(s). In certain embodiments, the isolation solvent(s) can be the same as the purification solvent(s) or polymerization solvent(s). In other embodiments, the isolation solvent(s) can be different from the purification solvent(s) or polymerization solvent(s). In some embodiments, the isolation solvent(s) are compatible with various coating and application methods employed in many industrial applications.

In some embodiments, the isolation solvent(s) can include a ketone, an ester, a hydrocarbon, a sulfoxide, an ether, or a mixture thereof. Examples of suitable isolation solvent(s) include, but are not limited to, methyl ethyl ketone (MEK), methyl isobutyl ketone (MIBK), 2-heptanone, cyclopentanone, cyclohexanone, xylene, gamma-butyrolactone, dimethylsulfoxide, propylene glycol monomethyl ether acetate (PGMEA), propylene glycol monomethyl ether (PGME), ethyl lactate (EL) and mixtures thereof.

In some embodiments, the isolation solvent(s) can be first added to the washed, purified organic solution containing a poly-o-hydroxyamide polymer. In such embodiments, the purification solvent(s) can then be removed by evaporation or distillation. In some embodiments, the amount of residual purification solvent(s) remaining after this step can be at most about 2 wt % (e.g., at most about 1 wt %) of the weight of the poly-o-hydroxyamide polymer. Without wishing to be bound by theory, it is believed that adding an isolation solvent(s) have a boiling point higher than that of the purification solvent(s) can facilitate the removal of the purification solvent(s) during distillation.

Without wishing to be bound by theory, it is believed that, in addition to exchanging the purification solvent(s) for the isolation solvent(s), this step also serves to dry the final polymer solution by removing residual water along with the purification solvent(s) (e.g., through distillation).

In some embodiments, after at least a portion (e.g., substantially all) of the purification solvent(s) is exchanged for the isolation solvent(s), the solution containing the poly-o-hydroxyamide polymer can be concentrated to form a solution suitable for further reaction, for example an endcapping reaction of the poly-o-hydroxyamide, or a hydroxyl group blocking reaction.

The distillation conditions can be any temperature and pressure under which the polymer is stable that will produce the desired end result. In some embodiments, the distillation temperature is from about 20° C. to about 70° C. (e.g., from about 25° C. to about 45° C.). In some embodiments, the distillation pressure is from about 760 Torr to about 0.1 Torr (e.g., from about 100 Torr to about 0.1 Torr). While the process detailed above leads to poly-o-hydroxyamide polymers of enhanced purity, it should be noted that additional process steps including, but not limited to, ion exchange and filtration may be included before and/or after steps 3 and 4 in this process.

In some embodiments, a purified poly-o-hydroxyamide polymer can be isolated from the solution obtained above by any suitable method known in the art (e.g., by precipitation or removal of solvents via distillation).

The poly-o-hydroxyamides of this disclosure have a hydroxyl group concentration of 3.35 mol/Kg or more when it does not contain a fluoride atom. When it is 4.0-10.0 mol/Kg and contains a fluoride atom, the hydroxyl group concentration is not less than 2.00 mol/Kg, preferably 3.0-10.0 mol/Kg. When the hydroxyl concentration is lower than these numerical values, there is a disadvantage that the poly-o-hydroxyamide polymers is not sufficiently dissolved in an alkaline aqueous solution.

In another embodiment, the unexposed photosensitive film including at least one poly-o-hydroxyamide of the disclosure has a dissolution rate of less than 0.05 um/sec in an aqueous alkaline solution with a pH greater than 8.0. In some embodiment, the unexposed photosensitive film including at least one poly-o-hydroxyamide of the disclosure has a dissolution rate of less than 0.01 um/sec in a 2.38 percent tetramethylammonium hydroxide aqueous solution.

The negative tone photosensitive compositions of the disclosure contain latent crosslinkers with at least two methylolated or methylolated and etherified compounds which generate reactive intermediates in the presence of heat, or in the presence of thermogenerated or photogenerated acids. Any suitable amino or phenolic crosslinking agent may be used as a latent crosslinker in the compositions of the disclosure, such as methylolated and/or methylolated etherified guanamines, methylolated and/or methylolated and etherified melamines, methylolated and/or methylolated and etherified glycouril, methylolated and/or methylolated and etherified polyphenol and the like. Examples of suitable melamine cross-linking agents are methoxyalkylmelamines such as hexamethoxymethylmelamine, trimethoxymethylmelamine, hexamethoxyethylmelamine, tetramethoxy-ethylmelamine, hexamethoxypropylmelamine, pentamethoxypropylmelamine, and the like. In some embodiments the melamine cross-linking agent is hexamethoxymethyl-melamine. In some embodiments aminocrosslinking agents are MW100LM melamine crosslinker from Sanwa Chemical Co. Ltd., Kanaxawa-ken, Japan; Cymel 303 and Cymel 1171, from Cytec Industries West Patterson, New Jersey.

Examples of suitable melamine cross-linking agents are Powderlink 1174 from Cytec Industries West Patterson, New Jersey, and Powderlink 1174. Specific examples of hydroxymethyl-substituted polyfunctional phenols used as crosslinker precursor are 4,4′-[1,4-phenylenebis(methylidene)]bis(3,5-dihydroxymethyl phenol), 4,4′-[1,4-phenylenebis(1-ethylidene)]bis(3,5-dihydroxymethyl phenol), 4,4′-[1,4-phenylenebis(1-propylidene)]bis(3,5-dihydroxymethyl phenol), 4,4′-[1,4-phenylenebis(1-butylidene)]bis(3,5-dihydroxymethyl phenol), 4,4′-[1,4-phenylenebis(1-pentylidene)]bis (3,5-dihydroxymethyl phenol), 4,4′-[1,4-phenylenebis(1-methyl ethylidene)]bis(3,5-dihydroxymethyl phenol), 4,4′-[1,4-phenylenebis(1-ethyl propylidene)]bis(3,5-dihydroxymethyl phenol), 4,4′-[1,4-phenylenebis(1-propyl butylidene)]bis(3,5-dihydroxymethyl phenol), 4,4′-[1,4-phenylenebis(1-butyl pentylidene)]bis(3,5-dihydroxymethyl phenol), 4,4′-[1,3-phenylenebis(methylidene)]bis(3,5-dihydroxymethyl phenol), 4,4′-[1,3-phenylenebis(1-methyl ethylidene)]his (3,5-dihydroxymethyl phenol), 4,4′-[1,3-phenylenebis(1-ethyl propylidene)]bis(3,5-dihydroxymethyl phenol), 4,4′-[1,3-phenylenebis(1-propyl butylidene)]bis(3,5-dihydroxymethyl phenol) and 4,4′-[1,3-phenylenebis(1-butyl pentylidene)]bis(3,5-dihydroxymethyl phenol) are given as specific examples of hydroxymethyl-substituted polyfunctional phenols as crosslinker precursor. More examples of crosslinking agents are given below where G is a methylol or etherified methylolated group. Crosslinkers employed in this disclosure can be purchased commercially, or prepared by hydroxymethylation or alkoxymethylation of the corresponding phenols using standard techniques known to those skilled in the art. The preferred phenol crosslinker is 4-[1-[4-[1,1-bis[4-hydroxy-3,5-bis(methoxymethyl)phenyl]ethyl]phenyl]-1-methylethyl]-2,6-bis(methoxymethyl) phenol available under the commercial name of CLR-19-MF from Honshu Chemical Industries Co. Ltd., Tokyo, Japan. Further examples of crosslinking agents are described in, e.g., U.S. Pat. Nos. 5,488,182 and 6,777,161 and 8,153,346; the contents of which are hereby incorporated by reference.

The negative tone photosensitive compositions of this disclosure can optionally comprise a basic compound selected from the group consisting of tertiary amines having alkyl and/or aromatic groups, hindered secondary amines, non-aromatic cyclic amines and quaternary ammonium hydroxides.

Examples of tertiary amines include, but are not limited to, N,N-dimethylcyclohexylamine, N,N-diethylcyclohexylamine, N-methyldicyclohexylamine, N,N-dimethylethanolamine and the like. Examples of hindered secondary amines include, but are not limited to, diphenylamine, dicyclohexylamine, di-t-butylamine, t-butyl-phenylamine, t-butyl-cyclohexylamine, diisopropylamine, di-t-amylamine, phenyl-cyclohexylamine, phenyl-naphthylamine, dinaphthylamine, dianthracenylamine, and the like. Examples of suitable non-aromatic cyclic amines but are not limited to morpholine, N-methylmorpholine, 2,6-dimethylmorpholine, 2,2,6,6-tetramethylmorpholine, N-hydroxyethyl morpholine, N-ethyl morpholine, thiomorpholine, N-methylthiomorpholine, 2,6-dimethylthiomorpholine, 2,2,6,6-tetramethylthiomorpholine, piperidine, N-hydroxyethylpiperidine, 2,6-dimethyl piperidine, 2,2,6,6-tetramethylpiperidine, pyrrolidine, N-methylpyrrolidine, N-ethyl pyrrolidine, 2,5-dimethylpyrrolidine 2,2,5,5-tetramethylpyrrolidine, piperazine, N, N′-dimethylpiperazine, and N, N′-diethylpiperazine.

Examples of hindered cyclic amines include 5-diazabicyclo[4.3.0]non-5-ene, and 1,8-diazabicyclo[5.4.0]undec-7-ene and the like. Examples of amine include 1-phenylpiperidine, N,N-diethylaniline, N-phenyl diethanolamine, N-phenyl dipropanolamine, tripropylamine, N-(diethoxymethyl)aniline, N-(ethoxymethyl)-N-methylaniline, N-phenyl diethoxyethanolamine and the like. Examples of such amines have been described, e.g., in U.S. Pat. No. 9,519,216, the entire contents of which are hereby incorporated by reference.

The amount of basic compound ranges from about 0.5 to about 80% (mole) based on amount of PAG (photoacid generator). In some embodiments the amount of basic compound is from about 1 to about 40% (mole) based on the amount of PAG. In some embodiments the amount of basic compound is from about 2 to about 20% (mole) based on the amount of PAG. In some embodiments the amount of basic compound is from about 3 to about 10% (mole) based on the amount of PAG.

In some embodiments, the amount of the poly-o-hydroxyamide is at least about 0.1 wt. % (e.g., at least about 0.5 wt. %, at least about 1 wt %, at least about 2 wt %, at least about 5 wt %, at least about 10 wt %, at least about 15 wt %, or at least about 20 wt %) and/or at most or about 55 wt % (e.g., at most about 50 wt %, at most about 45 wt %, at most about 40 wt %, at most about 35 wt %, at most about 30 wt %, at most about 25 wt %, at most about 20 wt %, at most about 15 wt %, or at most about 10 wt %) of the solid weight of the negative tone photosensitive compositions described herein.

In some embodiments, the negative tone photosensitive compositions described herein can include at least one (e.g., two, three, or four) photobase generator. For example, when a negative tone photosensitive composition includes a photosensitive polymer having an acid labile functional group, the composition can be include a photoacid generator (such as those described above) to remove the acid labile functional groups and create a solubility contrast. To control acid diffusion, the composition can include a photobase generator to quench the additional acid to create a solubility contrast. Examples of suitable photobase generators include 9-anthrylmethyl N,N-diethylcarbamate (WPBG-018), 1,2-dicyclohexyl-4,4,5,5-tetramethylbiguanidium, n-butyltriphenylborate (WPBG-300), and the like. In some embodiments, the photobase generator described herein can be in an amount of from at least about 0.1 wt % (e.g., at least about 0.2 wt %, at least about 0.4 wt %, at least about 0.5 wt %, at least about 0.6 wt %, at least about 0.8 wt %, or at least about 1 wt %) to at most about 2 wt % of the solid weight of a negative tone photosensitive composition described herein.

In some embodiments, the negative tone photosensitive compositions of the disclosure contain one or more compounds which release acid upon exposure to radiation. Such materials are commonly called photoacid generators (PAGs). PAGs used in the compositions of the disclosure are active to radiation in the wavelength of between about 300 nm to about 460 nm. PAGs are soluble in the photosensitive composition and produce strong acid upon irradiation. Examples of such strong acids include hydrogen halides or a sulfonic acid. The classes of such PAGs include, but are not limited to, oxime sulfonates, triazines, diazoquinone sulfonates, aromatic sulfonyl imides or sulfonium or iodonium salts of sulfonic acids. Examples of such photoacid generators have been described, e.g., in U.S. Pat. Nos. 6,143,467 and 9,519,216, the entire contents of which are hereby incorporated by reference. Other suitable photoacid generators are perfluoroalkyl sulfonyl methides and perfluoroalkyl sulfonyl imides as disclosed in U.S. Pat. No. 5,554,664 which is incorporated herein by reference.

Other suitable examples of photoacid generators are triphenylsulfonium bromide, triphenylsulfonium chloride, triphenylsulfonium iodide, triphenylsulfonium hexafluorophosphate, triphenylsulfonium hexafluoroarsenate, triphenylsulfonium hexafluoroarsenate, triphenylsulfonium trifluoromethanesulfonate, diphenylethylsulfonium chloride, phenacylidimethylsulfonium chloride, phenacyltetrahydrothiophenium chloride, 4-nitrophenacyltetrahydrothiopheniumn chloride, and 4-hydroxy-2-methylphenylhexahydrothiopyrylium chloride.

Additional examples of suitable photoacid generators for use in the compositions of the disclosure include triphenylsulfonium perfluorooctanesulfonate, triphenylsulfonium perfluorobutanesulfonate, methylphenyldiphenylsulfonium perfluorooctanesulfonate, methylphenyldiphenylsulfonium perfluorooctanesulfonate, 4-n-butoxyphenyldiphenylsulfonium perfluorobutanesulfonate, 2,4,6-trimethylphenyldiphenylsulfonium perfluorobutanesulfonate, 2,4,6-trimethylphenyldiphenylsulfonium benzenesulfonate, 2,4,6-trimethylphenyldiphenylsulfonium 2,4,6-triisopropylbenzenesulfonate, phenylthiophenyldiphenylsulfonium 4-dodecylbenzensulfonic acid, tris(-t-butylphenyl)sulfonium perfluorooctanesulfonate, tris(-t-butylphenyl)sulfonium perfluorobutanesulfonate, tris(-t-butylphenyl)sulfonium 2,4,6-triisopropylbenzenesulfonate, tris(-t-butylphenyl)sulfonium benzenesulfonate, and phenylthiophenyldiphenylsulfonium perfluorooctanesulfonate.

Examples of suitable iodonium salts for use in this invention include, but are not limited to, diphenyl iodonium perfluorobutanesulfonate, bis-(t-butylphenyl)iodonium perfluorobutanesulfonate, bis-(t-butylphenyl)iodonium perfluorooctanesulfonate, diphenyl iodonium perfluorooctanesulfonate, bis-(t-butylphenyl)iodonium benzenesulfonate, bis-(t-butylphenyl)iodonium 2,4,6-triisopropylbenzenesulfonate, and diphenyliodonium 4-methoxybenzensulfonate. Further examples of suitable photoacid generators for use in this invention are bis(p-toluenesulfonyl)diazomethane, methylsulfonyl p-toluenesulfonyldiazomethane, 1-cyclo-hexylsulfonyl-1-(1,1-dimethylethylsulfonyl)diazomethane, bis(1,1-dimethylethylsulfonyl)diazomethane, bis(1-methylethylsulfonyl)diazomethane, bis(cyclohexylsulfonyl)diazomethane, 1-p-toluenesulfonyl-1-cyclohexylcarbonyldiazomethane, 2-methyl-2-(p-toluenesulfonyl)propiophenone, 2-methanesulfonyl-2-methyl-(4-methylthiopropiophenone, 2,4-methyl-2-(p-toluenesulfonyl)pent-3-one, 1-diazo-1-methylsulfonyl-4-phenyl-2-butanone, 2-(cyclohexylcarbonyl-2-(p-toluenesulfonyl)propane, 1-cyclohexylsulfonyl-1 cyclohexylcarbonyldiazomethane, 1-diazo-1-cyclohexylsulfonyl-3,3-dimethyl-2-butanone, 1-diazo-1-(1,1-dimethylethylsulfonyl)-3,3-dimethyl-2-butanone, 1-acetyl-1-(1-methylethylsulfonyl)diazomethane, 1-diazo-1-(p-toluenesulfonyl-3,3-dimethyl-2-butanone, 1-diazo-1-benzenesulfonyl-3,3-dimethyl-2-butanone, 1-diazo-1-(p-toluenesulfonyl)-3-methyl-2-butanone, cyclohexyl 2-diazo-2-(p-toluenesulfonyl)acetate, tert-butyl 2-diazo-2-benzenesulfonylacetate, isopropyl-2-diazo-2-methanesulfonylacetate, cyclohexyl 2-diazo-2-benzenesulfonylacetate, tert-butyl 2 diazo-2-(p-toluenesulfonyl)acetate, 2-nitrobenzyl p-toluenesulfonate, 2,6-dinitrobenzyl p-toluenesulfonate, and 2,4-dinitrobenzyl p-trifluoromethylbenzenesulfonate. The photoacid generators are described in described in, e.g., U.S. Pat. Nos. 6,143,467 and 5,883,221; the contents of which are hereby incorporated by reference.

In some embodiments, the negative tone photosensitive compositions described herein can include at least one (e.g., two, three, or four) photosensitizer, where the photosensitizer can absorb light in the wavelength range of from about 150 nm to about 600 nm (e.g., at about 405 nm). Examples of suitable photosensitizers that can be used in the dielectric film forming compositions of the disclosure include benzophenone compounds, thioxanthone compounds, anthraquinone compounds, anthracene compounds, coumarine compounds, and mixtures thereof. Some examples of photosensitizers include, but are not limited to, 9-methylanthracene, 9,10-dibutoxyanthracene, 9,10-diethoxyanthracene, anthracenemethanol, acenaphthylene, thioxanthone, methyl-2-naphthyl ketone, 4-acetylbiphenyl, and 1,2-benzofluorene. Examples of other photosensitizers are disclosed in, e.g., U.S. Application Publication No. 2022/0171285, the entire contents of which are hereby incorporated by reference. In some embodiments, the acyl germanium compounds described herein can serve as a photosensitizer.

In some embodiments, the amount of a photosensitizer is from at least about 0.01 wt % (e.g., at least about 0.05 wt %, at least about 0.1 wt %, or at least about 0.5 wt %) to at most about 1 wt % (e.g., at most about 0.8 wt %, at most about 0.6 wt %, at most about 0.5 wt %, at most about 0.4 wt %, at most about 0.2 wt % of the solid weight of a dielectric film forming composition described herein.

In some embodiments, the negative tone working photosensitive compositions described herein can further include one or a mixture (e.g., two, three, or four) of organic solvents. In some embodiments, the solvents are selected from group consisting of alkylene carbonates, lactones, cycloketones, linear ketones, alkyl esters; alkyl ester alcohol, alkyl ether alcohols, alkyl ether ester, glycol ester; glycol ether, cyclic ether, pyrrolidone, and dialkylsulfoxide and their mixture thereof. Examples of organic solvents suitable for the dielectric film forming compositions described herein include, but are not limited to, alkylene carbonates such as ethylene carbonate, propylene carbonate, butylene carbonate, and glycerine carbonate; lactones such as gamma-butyrolactone, ε-caprolactone, γ-caprolactone and γ-valerolactone; cycloketones such as cyclopentanone and cyclohexanone; linear ketones such as methyl ethyl ketone (MEK) and methyl isobutyl ketone (MIBK); esters such as n-butyl acetate; ester alcohol such as ethyl lactate; ether alcohols such as tetrahydrofurfuryl alcohol; ether ester such as (tetrahydrofuran-2-yl)methyl acetate, methyl-3-methoxypropionate, ethyl-3-ethoxypropionate and 3-methoxy butyl acetate; glycol esters such as propylene glycol methyl ether acetate; glycol ethers such as propylene glycol methyl ether (PGME); cyclic ethers such as tetrahydrofuran (THF); pyrrolidones such as N-methyl-2-pyrrolidone, N-ethyl-2-pyrrolidone or N-butyl-2-pyrrolidone or TamiSolve™ NxG; and dialkyl sulfoxide such as dimethyl sulfoxide. Additionally, a bioderived lactone, gamma-valerolactone, which can be derived from corn and sugar cane; a bioderived ketone, cyrene, which can be derived from corn and sugar cane; bioderived ether, 2-methyl tetrahydrofuran, which can be derived from lignocellulosic biomasses; a bioderived alcohol, glycerol, which can be derived from vegetable oils, bioderived alkyl alicyclics included limonenes (e.g., d-limonene) and pinenes (e.g., α-pinene), which can be derived from oil wastes or citrus wastes; bioderived alkyl alicyclics included cymenes (e.g., p-cymene), which can be derived from oil wastes or citrus wastes are suitable solvent or cosolvent for dielectric film forming compositions comprising poly-o-hydroxyamides.

In some embodiments, the total amount of the solvent is at least about 20 wt. % (e.g., at least about 25 wt. %, at least about 30 wt. %, at least about 35 wt. %, at least about 40 wt. %, at least about 45 wt. %, at least about 50 wt. %, at least about 55 wt. %, at least about 60 wt. %, or at least about 65 wt. %) and/or at most about 98 wt. % (e.g., at most about 95 wt. %, at most about 90 wt. %, at most about 85 wt. %, at most about 80 wt. %, at most about 75 wt. %, at most about 70 wt. %, or at most about 60 wt. %) of the total weight of the dielectric film forming compositions described herein.

In some embodiments, the negative tone photosensitive compositions described herein optionally include at least one (e.g., two, three, or four) filler (such as an inorganic filler or an inorganic particle). In some embodiments, the inorganic filler is selected from the group consisting of silica, alumina, titania, zirconia, hafnium oxide, CdSe, CdS, CdTe, CuO, zinc oxide, lanthanum oxide, niobium oxide, tungsten oxide, strontium oxide, calcium titanium oxide, sodium titanate, barium sulfate, barium titanate, barium zirconate, and potassium niobate. The inorganic fillers are in a granular form of an average size of about 0.1-2.0 microns. In some embodiments, the filler is an inorganic particle containing a ferromagnetic material. Suitable ferromagnetic materials include elemental metals (such as iron, nickel, and cobalt) or their oxides, sulfides and oxyhydroxides, and intermetallics compounds such as Awaruite (Ni₃Fe), Wairaruite (CoFe), Co₁₇Sm₂, and Nd₂Fe₁₄B.

In some embodiments, the amount of the inorganic filler (e.g., silica filler) is at least about 1 wt. % (e.g., at least about 2 wt. %, at least about 5 wt. %, at least about 8 wt. %, or at least about 10 wt. %) and/or at most about 30 wt. % (e.g., at most about 25 wt. %, at most about 20 wt. %, or at most about 15 wt. %) of the solid weight of the dielectric film forming compositions described herein.

In some embodiments, the negative tone photosensitive compositions described herein can optionally include at least one (e.g., two, three, or four) adhesion promoter. Any suitable adhesion promoter may be employed. Classes of suitable adhesion promoters include, but are not limited to, vinylalkoxysilanes, methacryloxalkoxysilanes, mercaptoalkoxysilanes, epoxyalkoxysilanes and glycidoxyalkoxysilanes. Examples of suitable adhesion promoters include, but are not limited to, gamma-glycidoxypropylmethyldimethoxysilane, gamma-glycidoxypropyl-methyldiethoxysilane, gamma-mercaptopropylmethyldimethoxysilane, 3-methacryl-oxypropyldimethoxymethylsilane, and 3-methacryloxypropyltrimethoxysilane. gamma-glycidoxypropylmethyldimethoxysilane and the like. Suitable adhesion promoters are described in “Silane Coupling Agent Edwin P. Plueddemann, 1982 Plenum Press, New York. Examples of such adhesion promoters are disclosed in, e.g., U.S. Pat. Nos. 10,036,952 and 10,563,014, and U.S. Application Publication No. 2015/0219990, and EP Patent No. 3,492,982; the entire contents of which are hereby incorporated by reference.

In some embodiments, the amount of the optional adhesion promoter is at least about 0.5 wt. % (e.g., at least about 0.8 wt. %, at least about 1 wt. %, or at least about 1.5 wt. %) and/or at most about 4 wt. % (e.g., at most about 3.5 wt. %, at most about 3 wt. %, at most about 2.5 wt. %, or at most about 2 wt. %) of the solid weight of the dielectric film forming compositions described herein.

In some embodiments, the negative tone photosensitive compositions described herein can optionally contain at least one (e.g., two, three, or four) surfactant. Examples of suitable surfactants include, but are not limited to, the surfactants described in JP-A-62-36663, JP-A-61-226746, JP-A-61-226745, JP-A-62-170950, JP-A-63-34540, JP-A-7-230165, JP-A-8-62834, JP-A-9-54432 and JP-A-9-5988, the entire contents of which are hereby incorporated by reference.

In some embodiments, the amount of the surfactant is at least about 0.005 wt. % (e.g., at least about 0.01 wt. % or at least about 0.1 wt. %) and/or at most about 1 wt. % (e.g., at most about 0.5 wt. % or at most about 0.2 wt. %) of the solid weight of the dielectric film forming compositions described herein.

In some embodiments, the negative tone photosensitive compositions described herein can optionally contain at least one (e.g., two, three, or four) corrosion inhibitor. Examples of suitable corrosion inhibitors include triazole compounds, imidazole compounds and tetrazole compounds. Triazole compounds can include triazoles, benzotriazoles, substituted triazoles, and substituted benzotriazoles. The negative tone photosensitive compositions including corrosion inhibitors prevent corrosion and discoloration of copper or copper alloy when the photosensitive compositions are used on top of the copper or copper alloy. In addition, the corrosion inhibitor can play a significant role in improving HAST stability of TEG chip by effectively binding in copper.

Examples of tetrazoles include 1-H-tetrazole, 5-methyl-1H-tetrazole, 5-phenyl-1H-tetrazole, 5-(ethylthio)-1H-tetrazole, 5-(benzylthio)-1H-tetrazole, ethyl 1H-tetrazole-5-acetate, ethyl 1H-tetrazole-5-carboxylate, 5-amino-1H-tetrazole, 1-phenyl-5-mercapto-1H-tetrazole, 5,5′-bis-1H-tetrazole, 1-methyl-5-ethyltetrazole, 1-methyl-5-mercaptotetrazole, 1-carboxymethyl-5-mercaptotetrazole, 5-amino-1H-tetrazole, 1-methyl-1H-tetrazole and the like.

Examples of triazole compounds of include, but are not limited to, 1,2,4-triazole, 1,2,3-triazole, or triazoles substituted with substituents such as C₁-C₈ alkyl (e.g., 5-methyltriazole), amino, thiol, mercapto, imino, carboxy and nitro groups. Further examples of triazoles include 1,2,4-triazole, 1,2,3-triazole, 5-methyl-1,2,4-triazole, 3-amino-5-mercapto-1,2,4-triazole, 1-amino-1,2,3-triazole, 1-amino-5-methyl-1,2,3-triazole, 3-amino-1,2,4-triazole, 3-mercapto-1,2,4-triazole, 3-isopropyl-1,2,4-triazole, and the like.

Examples of benzotriazole of include 1-H benzotriazole, tolyltriazole, 5-phenyl-benzotriazole, 5-nitro-benzotriazole, hydroxybenzotriazole, 2-(5-amino-pentyl)-benzotriazole, 5-phenylthiol-benzotriazole, 5-methyl-1H-benzotriazole, 4-methyl-1H-benzotriazole, 4-carboxy-1H-benzotriazole, 5-carboxy-1H-benzotriazole, 2-hydroxy-5-acrylyloxyphenyl-2H-benzotriazoles, 2-(5-methyl-2-hydroxyphenyl) benzotriazole, 2-(3-t-butyl-phenyl) 5-methyl-2-hydroxy-benzotriazole, 2-(3,5-di-t-amyl-2-hydroxyphenyl) benzotriazole, 2-hydroxy-3-chloro-5-acrylyloxyphenyl-2H-benzotriazoles and the like.

Examples of imidazole include, but are not limited to, 2-alkyl-4-methyl imidazole, 2-phenyl-4-alkyl imidazole, 2-methyl-4(5)-nitroimidazole, 5-methyl-4-nitroimidazole, 4-Imidazolemethanol hydrochloride, and 2-mercapto-1-methylimidazole.

The amount of the optional corrosion inhibitor, if employed, is at least about 0.1 wt. % (e.g., at least about 0.2 wt. % or at least about 0.5 wt. %) and/or at most about 3.0 wt. % (e.g., at most about 2.0 wt. % or at most about 1.0 wt. %) of the solid weight of the dielectric film forming compositions described herein. If the amount of corrosion inhibitor is more than the range, the storage stability is reduced, if the amount of corrosion inhibitor s less than the above range, voids between the copper or copper alloy surface is likely to occur.

In some embodiments, the negative tone photosensitive compositions described herein include other optional components, such as one or more (e.g., two, three, or four) dyes, pigments, plasticizers, or antioxidants. Examples of such components have been described, e.g., in U.S. Application Publication No. 2022/0127459, the entire contents of which are hereby incorporated by reference.

In some embodiments, the negative tone photosensitive compositions of the disclosure include a plasticizer, wherein the amount of the plasticizer present in the composition is an amount effective to reduce the sidewall angle of imaged and cured features in the coated film on the substrate. As such, the plasticizer helps prevent stress failures in subsequent metallization of the substrate due to steep angles of the imaged features.

For some applications, microelectronic manufacturers and technologists request coating compositions that provide shallower or softer side wall geometries. If the sidewalls of the features that result from the photoimaging process are too vertical and/or form too sharp of an angle with the top surface of the coating, subsequent metallization of the features can lead to metal layers with high induced stress. Cracks and delamination of the metal layer may form in the regions of high stress. These cracks can propagate through the metal layer structure to such an extent that device functional failure results due to an open circuit. In addition, bond pads that have a coating with vertical side walls may be difficult to wire bond since the bonding head may not fit between the vertical walls. Clearly, a tapered sidewall with rounded edges is needed.

Thus, in some embodiments, the disclosure provides negative tone photosensitive compositions comprising poly-o-hydroxyamide polymers and a plasticizer that has a low vapor pressure at the typical soft bake temperatures (100-150 degrees centigrade) of the film. The presence of plasticizers in the formulation helps to provide shallower wall angles, or rounder corners and edges. For the purpose of this disclosure, a plasticizer is defined as a compound when present in the compositions of the disclosure is capable of producing such shallower wall angles and/or rounder corners and edges during the curing cycle of the poly-o-hydroxyamide polymer in features photoimaged from coatings cast from the compositions of this disclosure.

In some embodiments the disclosure provides negative tone photosensitive compositions including at least one plasticizer, wherein the plasticizer is a polyhydroxy compound with at least two OH groups, and wherein the boiling point of the plasticizer is higher than the boiling point of the negative tone photosensitive composition solvent. Examples of polyhydroxy compounds with at least two OH groups include, but are not limited to, ethylene glycol, diethylene glycol, polyethylene glycol, propylene glycol, tripropylene glycol, polypropylene glycol, glycerol, butane diol, hexane diol, sorbitol, cyclohexanediol, 4,8-bis(hydroxymethyl)-tricyclo(5.2.1.0/2,6)decane and a 2-oxepanone co-polymer with 2-ethyl-2-(hydroxymethyl)-1,3-propanediol, polycaprolactone triol (known as Placcel 305, Placcel 305T available from Daicel ChemTech Inc), and a silane diol such as diarylsilane diol or dialkylsilane diol. In some embodiments the polyhydroxy compounds with at least two OH groups are diethylene glycol, tripropylene glycol, and a 2-oxepanone co-polymer with 2-ethyl-2-(hydroxymethyl)-1,3-propanediol. In some embodiments the polyhydroxy compounds with at least two OH groups are tripropylene glycol and a 2-oxepanone co-polymer with 2-ethyl-2-(hydroxymethyl)-1,3-propanediol.

The amount of plasticizer used in the monovalent acid labile group containing negative working photosensitive poly-o-hydroxyamide precursor composition of this invention is from about 0.1 weight percent to about 20 weight percent of the total weight of the composition, preferably, from about 1 weight percent to about 10 weight percent, more preferably, from about 1.25 weight percent to about 7.5 weight percent and most preferably, from about 1.5 weight percent to about 5 weight percent. The plasticizers may be blended in any suitable ratio.

In some embodiments, the negative tone photosensitive compositions described herein are substantially fluorine-free. In other words, the poly-o-hydroxyamides, photoacid generators, basic compounds, photobase generators, sensitizers, adhesion promoters, surfactants, solvents, corrosion inhibitors, plasticizers and additives are substantially fluorine free. In other embodiments, the poly-o-hydroxyamides, photoacid generators, basic compounds, photobase generators, sensitizers, adhesion promoters, surfactants, solvents, corrosion inhibitors, plasticizers and additives are free of per- and polyfluoroalkyl substances (PFAS).

In some embodiments, the negative tone photosensitive compositions described herein are substantially halogen-free. In other words, the poly-o-hydroxyamides, photoacid generators, basic compounds, photobase generators, sensitizers, adhesion promoters, surfactants, solvents, corrosion inhibitors, plasticizers and additives are substantially halogen-free.

In other embodiments of the disclosure, there are provided methods for forming a patterned image on a substrate. Such methods can be performed, for example, by
(a) providing a substrate,
(b) coating on said substrate a negative tone photosensitive composition comprising: at least one poly-o-hydroxyamide having the structure (2), at least one solvent, at least one crosslinker, thereby forming a coated substrate;
(c) exposing the coated substrate to actinic radiation;
(d) post exposure baking the coated substrate at an elevated temperature;
(e) developing the coated substrate with an aqueous developer, thereby forming a relief image; and
(f) baking the substrate at an elevated temperature, thereby curing the relief image and forming a heat resistant film, thereby forming a patterned image on the substrate.

In some embodiments, a dielectric film can be prepared from a negative tone photosensitive composition described herein by a method including the steps of: (a) coating the negative tone photosensitive composition described herein on a substrate (e.g. a semiconductor substrate) to form a dielectric film; and (b) optionally baking the film at an elevated temperature (e.g., from about 50° C. to about 150° C.) for a period of time (e.g., from about 20 seconds to about 600 seconds).

Coating methods of the negative tone photosensitive composition include, but are not limited to, (1) spin coating, (2) spray coating, (3) roll coating, (4) rod coating, (5) rotation coating, (6) slit coating, (7) compression coating, (8) curtain coating, (9) die coating, (10) wire bar coating, (11) knife coating and (12) lamination of dry film. In case of coating methods (1)-(11), the negative tone photosensitive composition is typically provided in the form of a solution. One skilled in the art would choose the appropriate solvent type and solvent concentration based on the coating type.

Substrates can have circular, square or rectangular shapes such as wafers or panels in various dimensions. Examples of suitable substrates are epoxy molded compound (EMC), silicon, glass, copper, stainless steel, copper cladded laminate (CCL), aluminum, silicon oxide and silicon nitride. Substrates can be flexible such as polyimide, PEEK, polycarbonate, and polyester films. Substrates can have surface mounted or embedded chips, dyes, or packages. Substrates can be sputtered or pre-coated with a combination of seed layer and passivation layer. In some embodiments, the substrates mentioned herein can be a semiconductor substrate. As used herein, a semiconductor substrate is a substrate (e.g., a silicon or copper substrate or wafer) that becomes a part of a final electronic device.

The thickness of the films cast from negative tone photosensitive compositions of the disclosure is not particularly limited. In some embodiments, the dielectric film has a film thickness of at least about 1 micron (e.g., at least about 2 microns, at least about 3 microns, at least about 4 microns, at least about 5 microns, at least about 6 microns, at least about 8 microns, at least about 10 microns, at least about 15 microns, at least about 20 microns, or at least about 25 microns) and/or at most about 100 microns (e.g., at most about 90 microns, at most about 80 microns, at most about 70 microns at most about 60 microns, at most about 50 microns, at most about 40 microns, or at most about 30 microns). In some embodiments, the thickness of the dielectric film is less than about 5 microns (e.g., less than about 4.5 microns, less than about 4.0 microns, less than about 3.5 microns, less than about 3.0 microns, less than about 2.5 microns, or less than about 2.0 microns).

In some embodiments, films cast from the negative tone photosensitive compositions of the disclosure are converted into a patterned dielectric film by a lithographic method. In such cases, the conversion can include exposing the photosensitive dielectric film to high energy radiation (such as electron beams, ultraviolet light, and X-ray) using a patterned mask.

After the exposure, the dielectric film can be heat treated from at least about 50° C. (e.g., at least about 55° C., at least about 60° C., or at least about 65° C.) to at most about 100° C. (e.g., at most about 95° C., or at most about 90° C., at most about 85° C., at most about 80° C., at most about 75° C., or at most about 70° C.) for at least about 60 seconds (e.g., at least about 65 seconds, or at least about 70 seconds) to at most about 240 seconds (e.g., at most about 180 seconds, at most about 120 seconds or at most about 90 seconds). The heat treatment is usually accomplished by use of a hot plate or oven.

After the exposure and heat treatment, the dielectric film can be developed to remove unexposed portions by using a developer to form openings or a relief image on the substrate. Development can be carried out by, for example, an immersion method or a spraying method. Microholes and fine lines can be generated in the dielectric film on the laminated substrate after development.

In some embodiments, the dielectric film can be developed by using an aqueous developer. When the developer is an aqueous solution, it preferably contains one or more aqueous bases. Examples of suitable bases include, but are not limited to, inorganic alkalis (e.g., potassium hydroxide, sodium hydroxide, sodium carbonate, potassium carbonate), primary amines (e.g., ethylamine, n-propylamine), secondary amines (e.g., diethylamine, di-n-propylamine), tertiary amines (e.g., triethylamine), alcoholamines (e.g., triethanolamine), quaternary ammonium hydroxides (e.g., tetramethylammonium hydroxide or tetraethylammonium hydroxide), and mixtures thereof. The concentration of the base employed will vary depending on, e.g., the base solubility of the polymer employed. The most preferred aqueous developers are those containing tetramethylammonium hydroxide (TMAH). Suitable concentrations of TMAH range from about 1% to about 5%.

In some embodiments, after the development step or the optional rinse treatment step, an optional baking step (e.g., post development bake) can be carried out at a temperature ranging from at least about 120° C. (e.g., at least about 130° C., at least about 140° C., at least about 150° C., at least about 160° C., at least about 170° C., or at least about 180° C.) to at most about 250° C. (e.g., at most about 240° C., at most about 230° C., at most about 220° C., at most about 210° C., at most about 200° C. or at most about 190° C.). The baking time is at least about 5 minutes (e.g., at least about 10 minutes, at least about 20 minutes, at least about 30 minutes, at least about 40 minutes, at least about 50 minutes, or at least about 60 minutes) and/or at most about 5 hours (e.g., at most about 4 hours, at most about 3 hours, at most about 2 hours, or at most about 1.5 hours). This baking step can remove residual solvent from the remaining dielectric film and can further crosslink the remaining dielectric film. Post development bake can be done in air or preferably, under a blanket of nitrogen and may be carried out by any suitable heating means.

The benzoxazole ring is formed by curing of the uncured relief pattern to obtain the final high heat resistant pattern. Curing is performed by baking the developed, uncured relief pattern at or above the glass transition temperature (T_{g}) of the photosensitive composition to obtain the benzoxazole ring that provides high heat resistance. Typically, temperatures above about 200 C are used. In some embodiments, temperatures from about 250 degrees centigrade to about 400 degrees centigrade are applied. The curing time is from about 15 minutes to about 24 hours depending on the heating method employed. In some embodiments the curing time is from about 20 minutes to about 5 hours. In some embodiments the curing time is from about 30 minutes to about 3 hours. Curing can be done in air or under a blanket of nitrogen and may be carried by any suitable heating means, including baking on a hot plate or in a convection oven.

In some embodiments, the poly-o-hydroxyamide is cured at temperatures sufficient to effect cyclodehydration, thereby forming a benzoxazole ring wherein A1 and A2 are substituted or unsubstituted alkyl or aromatic group.

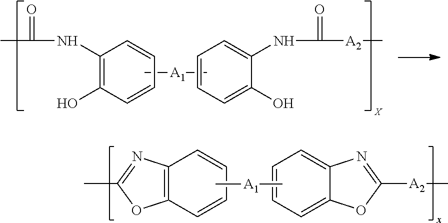

Curing of poly-o-hydroxyamides (2) and (3) provides (2c) and (3c).

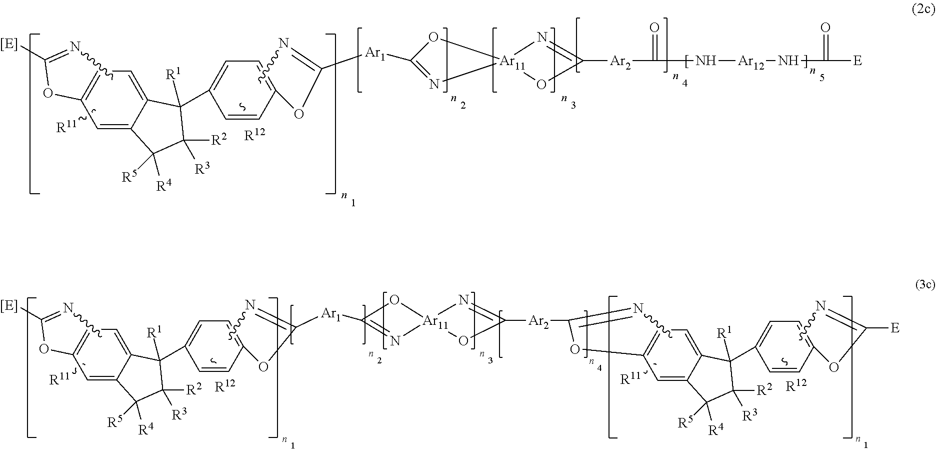

wherein R¹, R², R³, R⁴, R⁵, R¹¹, R¹², Ar₁, Ar₂, Ar₁₁, n¹, n², n³, n⁴ and E have the same meaning as described earlier.

In some embodiments, the patterned films cast from the negative tone photosensitive compositions of the disclosure include feature sizes of at most about 10 microns (e.g., at most about 9 microns, at most about 8 microns, at most about 7 microns, at most about 6 microns, at most about 5 microns, at most about 4 microns, at most about 3 microns, at most about 2 microns, or at most about 1 micron). In certain embodiments the films include feature sizes of at most about 3 microns (e.g., at most 2 microns or at most 1 micron) by a laser ablation method.

In some embodiments, the embodiment ratio (ratio of height to width) of a feature (e.g., the smallest feature) of the patterned dielectric film of this disclosure is at least about 1/3 (e.g., at least about 1/2, at least about 1/1, at least about 2/1, at least about 3/1, at least about 4/1, or at least about 5/1).

In some embodiments methods to prepare a patterned dielectric film include converting the dielectric film into a patterned dielectric film by a laser ablation technique (e.g., in embodiments of the disclosure wherein the compositions are not photosensitive). Direct laser ablation method with an excimer laser beam is generally a dry, one step material removal to form openings (or patterns) in the dielectric film. In some embodiments, the wavelength of the laser is 640 nm or less (e.g., 157 nm, 193 nm, 248 nm, 308 nm, 351 nm, 405 nm, 445 nm, 470 nm, 520 nm, 528 nm, 555 nm, or 640 nm). Examples of suitable laser ablation methods include, but are not limited to, the methods described in U.S. Pat. Nos. 7,598,167, 6,667,551, and 6,114,240, the contents of which are hereby incorporated by reference.

In embodiments wherein the compositions of the disclosure are non-photosensitive, the compositions can be used to form the bottom layer in a bilayer photoresist. In such embodiments, the top layer of the bilayer photoresist can be a photosensitive layer and can be patterned upon exposure to high energy radiation. The pattern in the top layer can be transferred to the bottom dielectric layer (e.g., by etching). The top layer can then be removed (e.g., by using a wet chemical etching method) to form a patterned dielectric film.

In some embodiments, this disclosure features a method for depositing a metal layer (e.g., to create an embedded copper trace structure) that includes the steps of: (a) forming a patterned dielectric film having openings; and d) depositing a metal layer (e.g., an electrically conductive metal layer) in at least one opening in the patterned dielectric film. In some embodiments, the method can include the steps of: (a) depositing a dielectric film forming composition described herein on a substrate (e.g., a semiconductor substrate) to form a dielectric film; (b) exposing the dielectric film to a source of radiation or heat or a combination thereof (e.g., through a mask); (c) patterning the dielectric film to form a patterned dielectric film having openings; and (d) depositing a metal layer (e.g., an electrically conductive metal layer) in at least one opening in the patterned dielectric film. In some embodiments, steps (a)-(d) can be repeated one or more (e.g., two, three, or four) times.

In some embodiments, this disclosure features a method to deposit a metal layer (e.g., an electrically conductive copper layer to create an embedded copper trace structure) on a semiconductor substrate. In some embodiments, a seed layer conformal to the patterned dielectric film is first deposited on the patterned dielectric film (e.g., outside the openings in the film). Seed layers can contain a barrier layer and a metal seeding layer (e.g., a copper seeding layer). In some embodiments, the barrier layer is prepared by using materials capable of preventing diffusion of an electrically conductive metal (e.g., copper) through the dielectric layer. Suitable materials that can be used for the barrier layer include, but are not limited to, tantalum (Ta), titanium (Ti), tantalum nitride (TiN), tungsten nitride (WN), and Ta/TaN. A suitable method of forming the barrier layer is sputtering (e.g., PVD or physical vapor deposition). Sputtering deposition has some advantages as a metal deposition technique because it can be used to deposit many conductive materials, at high deposition rates, with good uniformity and low cost of ownership. Conventional sputtering fill produces relatively poor results for deeper, narrower (high-embodiment-ratio) features. The fill factor by sputtering deposition has been improved by collimating the sputtered flux. Typically, this is achieved by inserting between the target and substrate a collimator plate having an array of hexagonal cells.

The next step in the method is metal seeding deposition. A thin metal (e.g., an electrically conductive metal such as copper) seeding layer can be formed on top of the barrier layer in order to improve the deposition of the metal layer (e.g., a copper layer) formed in the succeeding step.

The next step in the method is depositing an electrically conductive metal layer (e.g., a copper layer) on top of the metal seeding layer in the openings of the patterned dielectric film wherein the metal layer is sufficiently thick to fill the openings in the patterned dielectric film. The metal layer to fill the openings in the patterned dielectric film can be deposited by plating (such as electroless or electrolytic plating), sputtering, plasma vapor deposition (PVD), and chemical vapor deposition (CVD). Electrochemical deposition is generally a preferred method to apply copper since it is more economical than other deposition methods and can flawlessly fill copper into the interconnect features. Copper deposition methods generally should meet the stringent requirements of the semiconductor industry. For example, copper deposits should be uniform and capable of flawlessly filling the small interconnect features of the device, for example, with openings of 100 nm or smaller. This technique has been described, e.g., in U.S. Pat. Nos. 5,891,804, 6,399,486, and 7,303,992, the contents of which are hereby incorporated by reference.

In some embodiments, the method of depositing an electrically conductive metal layer further includes removing overburden of the electrically conductive metal or removing the seed layer (e.g., the barrier layer and the metal seeding layer). In some embodiments, the overburden of the electrically conductive metal layer (e.g., a copper layer) is at most about 3 microns (e.g., at most about 2.8 microns, at most about 2.6 microns, at most about 2.4 microns, at most about 2.2 microns, at most about 2.0 microns, or at most about 1.8 microns) and at least about 0.4 micron (e.g., at least about 0.6 micron, at least about 0.8 micron, at least about 1.0 micron, at least about 1.2 micron, at least about 1.4 micron, or at least about 1.6 microns). Examples of copper etchants for removing copper overburden include an aqueous solution containing cupric chloride and hydrochloric acid or an aqueous mixture of ferric nitrate and hydrochloric acid. Examples of other suitable copper etchants include, but are not limited to, the copper etchants described in U.S. Pat. Nos. 4,784,785, 3,361,674, 3,816,306, 5,524,780, 5,650,249, 5,431,776, and 5,248,398, and US Application Publication No. 2017/0175274, the contents of which are hereby incorporated by reference.

Some embodiments describe a method for surrounding a metal structured substrate containing conducting metal (e.g., copper) wire structures forming a network of lines and interconnects with the dielectric film described herein. The method includes
a) providing a substrate containing conducting metal wire structures that form a network of lines and interconnects on the substrate.
b) depositing a dielectric film forming composition described herein on the substrate to form a dielectric film (e.g., that surrounds the conducting metal lines and interconnects); and
c) exposing the dielectric film to a source of radiation or heat or a combination of radiation and heat (with or without a mask).

The above steps can be repeated multiple times (e.g., two, three, or four times) to form a complex multi-layered three-dimensional object.

In some embodiments, this disclosure features a method of preparing a dry film structure. The method includes:
a) coating a carrier substrate (e.g., a substrate including at least one polymeric or plastic film) with a dielectric film forming composition described herein.
b) drying the coated dielectric film forming composition to form a dielectric layer (e.g., a photosensitive, dielectric layer); and
c) optionally, applying a protective layer to the dry film structure.

In some embodiments, the carrier substrate is a single or multiple layer polymeric or plastic film, which can include one or more polymers (e.g., polyethylene terephthalate). In some embodiments, the carrier substrate has excellent optical transparency, and it is substantially transparent to actinic irradiation used to form a relief pattern in the polymer layer. The thickness of the carrier substrate is preferably in the range of at least about 10 μm (e.g., at least about 15 μm, at least about 20 μm, at least about 30 μm, at least about 40 μm, at least about 50 μm, or at least about 60 μm) to at most about 150 μm (e.g., at most about 140 μm, at most about 120 μm, at most about 100 μm, at most about 90 μm, at most about 80 μm, or at most about 70 μm).

In some embodiments, the protective layer is a single or multiple layer film, which can include one or more polymers (e.g., polyethylene or polypropylene). Examples of carrier substrates and protective layers have been described in, e.g., U.S. Application Publication No. 2016/0313642, the contents of which are hereby incorporated by reference.

Reliability is the probability that an electronic component will perform the required function under stressed conditions for a designated period. Preconditioning, Temperature Humidity Bias (THB), Biased Humidity Stress Test (bHAST), Unbiased HAST (uHAST), High Temp Storage (HTS) are commonly used stress test applied for semiconductor packaging materials. Reliability is measured as the proportion of devices used from time zero that will not have failed by a given time ‘t’.

The Highly Accelerated Stress Test (HAST) combines high temperature, high humidity, high pressure, and time to measure component reliability with or without electrical bias. In a controlled environment, HAST testing accelerates the stresses of the more traditional tests. It essentially functions as a corrosion failure test. Corrosion type failures are accelerated, uncovering flaws such as in packaging seals, materials, and joints over a short period of time.

Biased Highly Accelerated Stress Tests (bHAST) utilize the same variables (high pressure, high temperature and time) as HAST Tests, but add a voltage bias. The goal of BHAST testing is to accelerate corrosion within the device, thereby speeding up the test period. In unbiased HAST tests, humidity accelerates failure mechanisms related the presence of moisture for non-hermetic packages. Biased voltage under high humidity causes galvanic and electrochemical corrosion in non-hermitic packages in biased Humidity Stress Test (bHAST). For advanced/emerging package technologies, board level reliability (BLR) testing is conducted to determine the solder joint interconnect reliability using daisy-chained test vehicles. Failure analysis is conducted on failed samples to determine the cause.

As an accelerated version of the traditional non-condensing THB (temperature humidity bias) test, the HAST test has the advantage of adding high pressure and higher temperatures (up to 149° C.) to accelerate temperature and moisture induced failures in roughly one-tenth the time of THB. HAST and BHAST testing is usually run at 130° C./85% RH (where RH means relative humidity), but the conditions can also vary.

Typical HAST test conditions consist of 110 or 130° C. temperature, and 85% RH humidity and a test run time of 96 hours or 200 hours. Once the highly accelerated stress test is completed, tested samples are analyzed by microscope and SEM for changes happen during HAST conditions. HAST testing generally follows JEDEC spec JESD22 A110, “Highly Accelerated Temperature and Humidity Stress Test (HAST).” Biased Humidity Stress Test (bHAST) is the most sensitive stress test for reliability of a microelectronic device by using an organic dielectric film composition. Examples of bHAST methods used in evaluation of semiconductor devices have been described in, e.g., U.S. Pat. No. 9,874,813 and US patent application 2021/0272898 and the contents of which are hereby incorporated by reference.

TEG (Test Element Group) wafer with Cu post (pillar) plating was used for evaluation of wafer for such as material development, package stability under HAST conditions by inspection method. Examples of TEG wafers used in evaluation of semiconductor devices have been described in, e.g., U.S. Pat. Nos. 8,237,450 and 9,082,708, the contents of which are hereby incorporated by reference.

In some embodiments, the dielectric film of the dry film structure can be delaminated from carrier layer as a self-standing dielectric film. A self-standing dielectric film is a film that can maintain its physical integrity without using any support layer such as a carrier layer. In some embodiments, the self-standing dielectric film is not crosslinked or cured and can include the components of the dielectric film forming composition described above except for the solvent.

In some embodiments, the dielectric loss tangent or dissipation factor of the dielectric film prepared from negative tone photosensitive compositions of the disclosure is measured at 10 GHz, 15 GHz, and/or 35 GHz is in the range of from at least about 0.001 (e.g., at least about 0.002, at least about 0.003, at least about 0.004, at least about 0.005, at least about 0.01, or at least about 0.05) to at most about 0.1 (e.g., at most about 0.08, at most about 0.06, at most about 0.05, at most about 0.04, at most about 0.02, at most about 0.01, at most about 0.008, at most about 0.006, or at most about 0.005).

In some embodiments, the dielectric film of the dry film structure can be laminated to a substrate (e.g., a semiconductor substrate such as a wafer) using a vacuum laminator at about 50° C. to about 140° C. after pre-laminating of the dielectric film of the dry film structure with a plane compression method or a hot roll compression method. When the hot roll lamination is employed, the dry film structure can be placed into a hot roll laminator, the optional protective layer can be peeled away from the dielectric film/carrier substrate, and the dielectric film can be brought into contact with and laminated to a substrate using rollers with heat and pressure to form an article containing the substrate, the dielectric film, and the carrier substrate. The dielectric film can then be exposed to a source of radiation or heat (e.g., through the carrier substrate) to form a crosslinked dielectric film. In some embodiments, the carrier substrate can be removed before exposing the dielectric film to a source of radiation or heat.

Some embodiments of this disclosure describe a method of generating a planarizing dielectric film on a substrate with copper pattern. In some embodiments, the method includes depositing a dielectric film forming composition onto a substrate with copper pattern to form a dielectric film. In some embodiments, the method includes steps of:
a. providing a dielectric film forming composition of this disclosure, and
b. depositing the dielectric film forming composition onto a substrate with a copper pattern to form a dielectric film, wherein the difference in the highest and lowest points on a surface of the dielectric film is at most about 2 microns (e.g., at most about 1.5 microns, at most about 1 micron, or at most about 0.5 micron).

In some embodiments, this disclosure features an article (or a three-dimensional object) containing at least one patterned dielectric film formed by a method described herein. Examples of such articles include a semiconductor substrate, a flexible film for electronics, a wire isolation, a wire coating, a wire enamel, and an inked substrate. In some embodiments, this disclosure features semiconductor devices that include one or more of these articles. Examples of semiconductor devices that can be made from such articles include an integrated circuit, a light emitting diode, a solar cell, and a transistor.

The present disclosure is illustrated in more detail with reference to the following examples, which are for illustrative purposes and should not be construed as limiting the scope of the present disclosure.

### EXAMPLES

### Synthesis Example 1: Synthesis of Poly-o-Hydroxyamide Precursor

To a 250 mL three-necked round bottom jacketed flask equipped with a mechanical stirrer, nitrogen inlet and an addition funnel, 13.23 g indane bis-o-aminophenol [6-amino-3-(3′-amino-4′-hydroxyphenyl)-1,1,3-trimethyl-2,3-dihydro-1H-inden-5-ol], 3.71 g of pyridine and 70 g of NMP (N-methyl pyrrolidone) were added. The solution was stirred at room temperature until it was clear and then cooled at −5 to −9° C. To this solution, 3.85 g isophthalyl chloride (IC) and 5.60 g of 4,4′-oxydibenzoyl chloride dissolved in 21 g of NMP was added dropwise. After the addition, the resulting mixture was stirred at room temperature for 18 hours. Then, 1.06 g of pyridine and 2.20 g of nadic anhydride were added to the flask and the temperature was raised to 90° C. and stirred for 12 h. After cooling to room temperature, the viscous solution was precipitated in 1000 mL of de-ionized water. The polymer was s collected by filtration and washed with deionized water and then with a 50/50 water/methanol mixture. The polymer was dried under vacuum at 60° C. for 24 hours to give a poly-o-hydroxyamide precursor. Weight average molecular weight (Mw) was 13,200 measured by GPC.

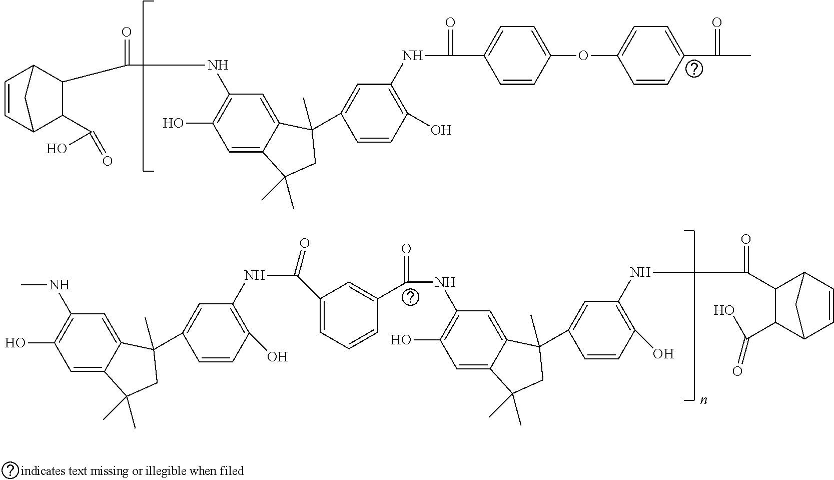

### Synthesis Example 2: Synthesis of Poly-o-Hydroxyamide Precursor

To a 1000 mL three-necked round bottom jacketed flask equipped with a mechanical stirrer, nitrogen inlet and an addition funnel, 63.2 g indane bis-o-aminophenol, 17.9 g of pyridine and 261 g of NMP were added. The solution was stirred at room temperature until it was clear and then cooled at −5 to −9° C. To this solution, 20.20 g isophthalyl chloride and 29.4 g of 4,4′-oxydibenzoyl chloride and 2.60 g of sebacoyl chloride dissolved in 200 g of NMP was added drop-wise. After the addition, the resulting mixture was stirred at room temperature for 18 hours. Then, 0.35 g of pyridine and 0.33 g of acetyl chloride were added to the flask and the temperature was raised to 90° C. and stirred for 12 h. The viscous solution was precipitated in 3000 mL of de-ionized water. The polymer was collected by filtration and washed with deionized water and then with a 50/50 water/methanol mixture. The polymer was dried under vacuum at 60° C. for 24 hours to give a poly-o-hydroxyamides precursor.

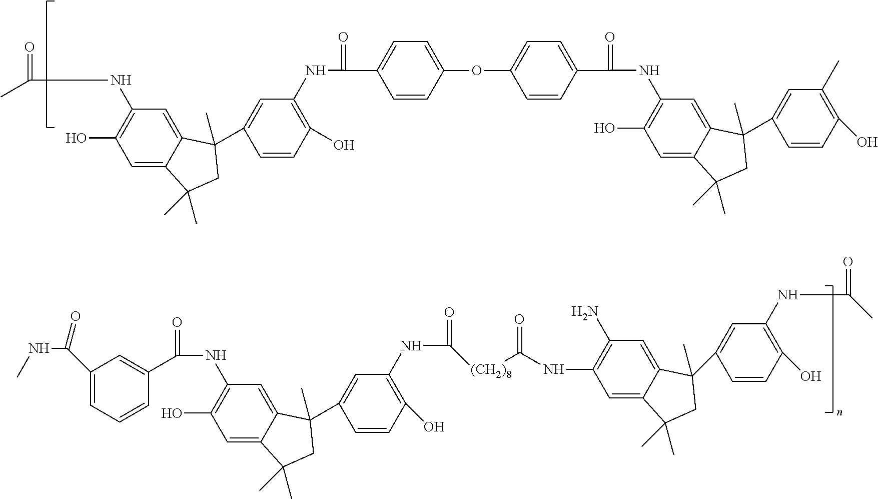

### Synthesis Example 3: Synthesis of Poly-o-Hydroxyamide Precursor

To a 1000 mL three-necked round bottom jacketed flask equipped with a mechanical stirrer, nitrogen inlet and an addition funnel, 59.3 g indane bis-o-aminophenol, 4.32 g 2,2-bis [4-(4-aminophenoxy)phenyl]propane (BAPP), 17.5 g of pyridine and 255 g of NMP are added. The solution is stirred at room temperature until it is clear and then cooled at −5 to −9° C. To this solution, 20.9 g isophthalyl chloride and 29.2 g of 4,4′-oxydibenzoyl chloride and 1.94 g of adipoyl chloride dissolved in 200 g of NMP is added drop-wise. After the addition, the resulting mixture is stirred at room temperature for 18 hours. Then, 0.35 g of pyridine and 0.40 g of acetyl chloride were added to the flask and the temperature was raised to 90° C. and stirred for 12 h. The viscous solution is precipitated in 3000 mL of de-ionized water. The polymer is collected by filtration and washed with deionized water and then with a 50/50 water/methanol mixture. The polymer is dried under vacuum at 60° C. for 24 hours to give a poly-o-hydroxyamides precursor.

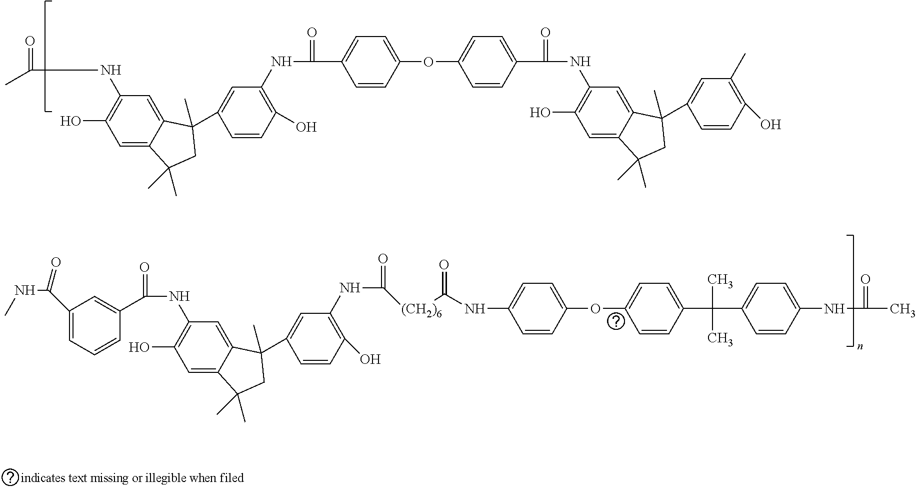

### Photosensitive Composition Example 1

A negative acting photosensitive composition is prepared by mixing 100 parts by weight of a polymer solution prepared by the method described in Synthesis Example 1, 3 parts by weight of triethoxysilylpropyl ethoxycarbamate, 0.102 parts by weight of N-phenyldiethanolamine, 5 parts by weight of (5-propylsulfonyloxyimino-5H-thiophen-2-ylidene)-2-methylphenyl-acetonitrile, 5 parts by weight tripropylene glycol, 10 parts Powderlink 1174 crosslinker from Cytec Industries, West Patterson, New Jersey, 0.1 parts by weight of 5-methyl-1H-benzotriazole, 0.1 parts by weights of Troysol S366 (available from Troy Corp. Inc) in 0.5% GBL, and 232 parts by weight GBL and is filtered through a 0.2 micro m Teflon filter.

A silicon wafer is then coated with the above photosensitive composition and hotplate baked for 3 minutes at 125 degrees centigrade, resulting in a film thickness of 9 micro m. The film is exposed utilizing an i-line stepper with a patterned exposure array. Segments of the film on the wafer are exposed at various levels of exposure energy using a Canon 4000 IE i-line stepper. The wafer is post exposure baked at 130 degrees centigrade for 90 seconds. The wafer is developed with 2.38 percent aqueous TMAH solution using two 30 second puddle development steps with spin steps to remove spent developer in between applications of developer. The developed film is rinsed with deionized water and dried by spinning for 10 seconds at 5000 rpm to provide a relief pattern. No unexposed film thickness loss is observed. 2 micro m and 8 micro m features are resolved at exposure energies of 200 mJ/cm² and 175 mJ/cm² respectively. The film is cured at 320° C. for 1 h under vacuum and formed polybenzoxazole film.

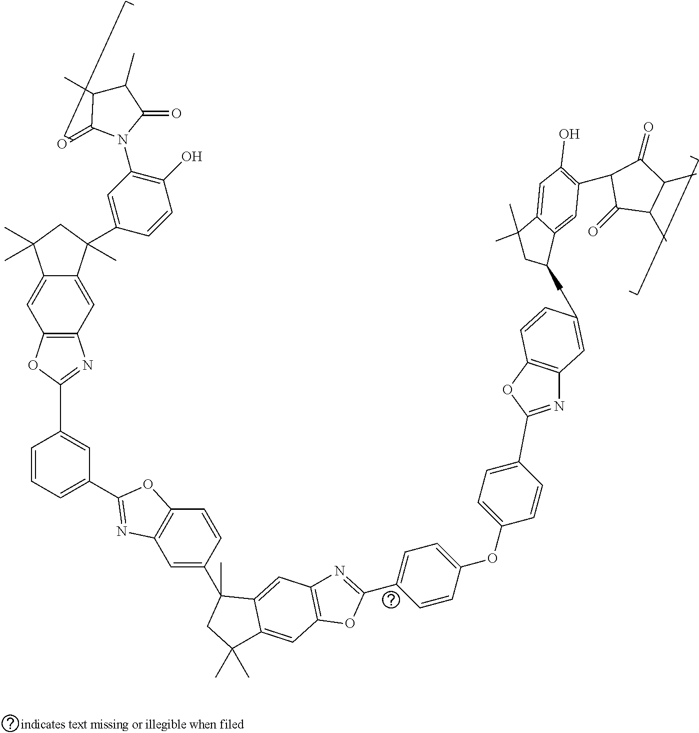

### Photosensitive Composition Example 2

A negative acting photosensitive composition is prepared by mixing 100 parts by weight of a polymer solution prepared by the method described in Synthesis Example 2, 5 parts by weight of (3-glycidoxypropyl)trimethoxysilane, 0.2 parts by weight of N-phenyl diethanolamine, 5 parts by weight of (5-propylsulfonyloxyimino-5H-thiophen-2-ylidene)-2-methylphenyl-acetonitrile, 10 parts by weight of 4-[1-[4-[1,1-bis[4-hydroxy-3,5-bis(methoxymethyl)phenyl]ethyl]phenyl]-1-methylethyl]-2,6-bis(methoxymethyl) phenol available under the commercial name of CLR-19-MF from Honshu Chemical Industries Co. Ltd., Tokyo, Japan., 10 parts by weight of polycaprolactone triol (known as Placcel 305, Placcel 305T available from Daicel ChemTech Inc), 0.1 parts by weight of 5-phenyl-1H-tetrazole, 0.1 parts by weights of Troysol S366 (available from Troy Corp. Inc) in 0.5% GBL, 231 parts by weight GBL and filtered through a 0.2 micro m Teflon filter.

A silicon wafer is then coated with the photosensitive composition from above and hotplate baked for 3 minutes at 115 degrees centigrade, resulting in a film thickness of 8.64 micro m. The film is exposed utilizing an i-line stepper with a patterned exposure array. Segments of the film on the wafer are exposed at various levels of exposure energy using a Canon 4000 IE i-line stepper. The wafer is post-exposure baked at 135 degrees centigrade for 90 seconds. The wafer is developed with 2.38 percent aqueous TMAH solution using one standing 60 second puddle development step. The developed film is rinsed with deionized water and dried by spinning for 10 seconds at 5000 rpm to provide a relief pattern. The film thickness after development is 8.49 micro m. Unexposed film thickness loss is 1.70 percent. 8 micro m features are resolved at an exposure energy of 335 mJ/cm². These features are carefully investigated by SEM and no chemical undercut was observed.

### Photosensitive Composition Example 3

A negative acting photosensitive composition is prepared by mixing 100 parts by weight of a polymer solution prepared by the method described in Synthesis Example 3, 3 parts by weight of triethoxysilylpropyl ethoxycarbamate, 0.217 parts by weight of 1,8-diazabicyclo[5.4.0]undec-7-ene (DBU), 10 parts by weight of the additive CLR-19-MF, available from Honshu Chemicals, 5 parts by weight of (5-propylsulfonyloxyimino-5H-thiophen-2-ylidene)-2-methylphenyl-acetonitrile, 10 parts by weight tripropylene glycol, 0.1 parts by weight of 1-H tetrazole, 0.1 parts by weights of Troysol S366 (available from Troy Corp. Inc) in 0.5% GBL, and 231 parts by weight GBL and is filtered through a 0.2 micro m Teflon filter.

The photosensitive formulation 3 is spin coated on the silicon wafer. The coated wafer is baked at 120 degrees centigrade for 4 minutes. The thickness of the film thus obtained is about 10.3 um. The coated silicon wafer is then exposed pattern-wise to broadband radiation measured with a 400 nm probe at an intensity of 5.5 MW/cm² for 54.5 seconds, resulting in an exposure energy of 300 mJ/cm². The wafer is baked for 180 seconds at 120 degrees centigrade and then developed in 0.262 N aqueous TMAH using multiple immersion development. The first immersion is for 100 seconds, and the second immersion is for 250 seconds with a DI water rinse between and after the develop steps. The remaining film is 9.6 micron thick after development is completed. 200 mum vias (square holes) are resolved.

### Photosensitive Composition Example 4

A negative acting photosensitive composition is prepared by mixing 100 parts by weight of a polymer solution prepared by the method described in Synthesis Example 3, 3 parts by weight of (3-glycidoxypropyl)trimethoxysilane, 0.08 parts by weight of AM 3662 2-{2-[2-(2,6-dimethoxyphenoxy)ethoxy]ethoxy}-N,N-bis(2-methoxyethyl)ethanamine, 10 parts of by weight TPG (tripropylene glycol), 4.4 parts by weight of (5-propylsulfonyloxyimino-5H-thiophen-2-ylidene)-2-methylphenyl-acetonitrile, 10 parts by weight MW100LM melamine crosslinker from Sanwa Chemical Co. Ltd., Kanaxawa-ken, Japan; 0.1 parts by weight of 5-methyl-1H-benzotriazole, 0.1 parts by weights of Troysol S366 (available from Troy Corp. Inc) in 0.5% GBL, 26 parts by weight of additional PGMEA, and 205 parts by weight GBL and is filtered through a 0.2 micro m Teflon filter.

The photosensitive formulation 3 is spin coated on the silicon wafer. The coated wafer is baked at 120 degrees centigrade for 4 minutes. The thickness of the film thus obtained is about 10.3 um. The coated silicon wafer is then exposed pattern-wise to broadband radiation measured with a 400 nm probe at an intensity of 5.5 MW/cm² for 54.5 seconds, resulting in an exposure energy of 300 mJ/cm². The wafer is baked for 180 seconds at 120 degrees centigrade and then developed in 0.262 N aqueous TMAH using multiple immersion development. The first immersion is for 100 seconds, and the second immersion is for 250 seconds with a DI water rinse between and after the develop steps. The remaining film is 9.6 micron thick after development is completed. 200 mum vias (square holes) are resolved.

### Photosensitive Composition Example 5

A negative acting photosensitive composition is prepared by mixing 100 parts by weight of a polymer solution prepared by the method described in Synthesis Example 1, 3 parts by weight of (3-glycidoxypropyl)trimethoxysilane, 0.1 parts by weight of N-phenyldiethanolamine, 4 parts of by weight TPG (tripropylene glycol), 4.4 parts by weight of (5-propylsulfonyloxyimino-5H-thiophen-2-ylidene)-2-methylphenyl-acetonitrile, 10 parts by weight of the additive CLR-19-MF, available from Honshu Chemicals, 26 parts by weight of additional PGMEA, and 205 parts by weight GBL and is filtered through a 0.2 micro m Teflon filter.

The photosensitive formulation 3 is spin coated on the silicon wafer. The coated wafer is baked at 120 degrees centigrade for 4 minutes. The thickness of the film thus obtained is about 10.3 um. The coated silicon wafer is then exposed pattern-wise to broadband radiation measured with a 400 nm probe at an intensity of 5.5 MW/cm² for 54.5 seconds, resulting in an exposure energy of 300 mJ/cm². The wafer is baked for 180 seconds at 120 degrees centigrade and then developed in 0.262 N aqueous TMAH using multiple immersion development. The first immersion is for 100 seconds, and the second immersion is for 250 seconds with a DI water rinse between and after the develop steps. The remaining film is 9.6 micron thick after development is completed. 200 mum vias (square holes) are resolved.

### Adhesion Tests

The coated wafers are baked at 120 degrees centigrade for 3 minutes. The thickness of the films thus obtained is 7-8 mum. The wafers are then exposed pattern-wise using a broadband mercury lamp light for 108.2 seconds (the lamp output is 1000 mJ/cm² at 400 nm during the exposure time) with Karl Suss MA-56 broadband exposure tool. A ten-by-ten grid of 2 mm squares is thus created. Then, the wafer is baked at 120 degrees centigrade for 2 minutes and developed in 0.262 N aqueous tetramethylammonium hydroxide using puddle development (2 puddles, 25 sec each). The patterned films is cured under N2 atmosphere at 320 degrees centigrade for 1 hour. The wafers are then placed in a pressure cooker pot and are exposed to saturated steam at 121 degrees centigrade for 100 hrs. Then, the adhesion of the films to the wafers is tested using a tape peel test using 3M tape #720 as described in ASTM D-3359-83. No squares of the grid are peeled off, and the formulation is passed the test. Both films have no adhesion losses after 1000 hours of the test.

While the invention has been described in detail with reference to certain embodiments thereof, it will be understood that modifications and variations are within the spirit and scope of that which is described and claimed.

What is claimed is:

1. A negative tone photosensitive composition comprising:
(a) at least one poly-o-hydroxyamide polymers having the structure 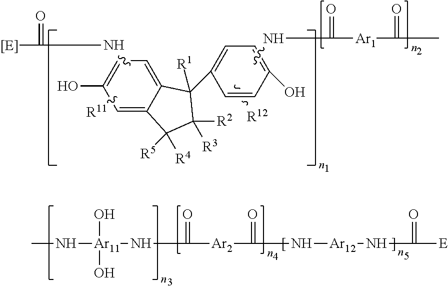
wherein each of R¹, R², R³, R⁴, and R⁵ independently, is a hydrogen atom, a substituted or unsubstituted C₁-C₁₂alkyl, a partially halogen substituted or fully halogen substituted C₁-C₁₂alkyl, a substituted or unsubstituted C₄-C₁₈ cycloalkyl, a substituted or unsubstituted C₆-C₂₂ aryl, or a substituted or unsubstituted C₅-C₂₂ heteroaryl; each of R¹¹ and R¹² is independently a hydrogen atom, a linear or branched C₁-C₄ alkyl, a partially halogen substituted or fully halogen substituted C₁-C₄alkyl, a C₅-C₁₂ cycloalkyl, a C₆-C₁₈ aryl, a C₅-C₁₈ heteroaryl group, a C₁-C₄ alkoxy group or a halogen atom; Ar₁ and Ar₂ are each independently a divalent aromatic, aliphatic, or heterocyclic group, or mixtures thereof; Ar₁₁ and A12 are a divalent aromatic, aliphatic, or heterocyclic group or a siloxane group; E is an end-capping group; n₁ is an integer from 5 to 200; n₃ is an integer from 0 to 200; n₅ is an integer from 0 to 200; n₂ is an integer from 5 to 200 and n₄ is an integer from 0 to 200;
(b) at least one photoacid generator;
(c) at least one latent crosslinker, and
(d) at least one solvent.

2. The negative tone photosensitive composition of claim 1, wherein said photoacid generator is selected from the group consisting of triazine compounds, sulfonates, disulfones, onium salts, and mixtures thereof.

3. The negative tone photosensitive composition of claim 2, wherein said photoacid generator is an onium salt selected from the group consisting of iodonium salt, sulfonium salt, phosphonium salt, diazonium salt, sulfoxonium salt, and mixtures thereof.

4. The negative tone photosensitive composition of claim 1, wherein said latent crosslinker contains at least two methylolated or methylolated and etherified compounds.

5. The negative tone photosensitive composition of claim 1, further comprising at least one plasticizer, wherein the plasticizer is a polyhydroxy compound with at least two OH groups, wherein the boiling point of the plasticizer is higher than the boiling point of negative tone photosensitive composition solvent.

6. The negative tone photosensitive composition of claim 1, further comprising at least one adhesion promoter.

7. The negative tone photosensitive composition of claim 1, further comprising at least one member selected from the group consisting of at least one surfactant, at least one filler, at least one pigment, and at least one dye.

8. The negative tone photosensitive composition of claim 1, wherein the at least one polymer is in an amount of from about 0.1% to about 55% by weight based on a solid weight of the composition.

9. A process for forming a heat resistant relief image on a substrate comprising the steps of:
a) coating on a substrate the negative tone photosensitive composition of claim 1,
b) exposing said coated substrate to actinic radiation,
c) post exposure baking said coated substrate at an elevated temperature,
d) developing said coated substrate with an aqueous developer, thereby forming a developed substrate; and
e) baking said developed substrate at an elevated temperature to convert the poly-o-hydroxyamide precursor to a polybenzoxazole, thereby forming a heat resistant relief image on the substrate.

10. The process of claim 9, wherein said actinic radiation is selected from the group consisting of X-rays, electron beam rays, ultraviolet rays, and visible light rays.

11. The process of claim 9, wherein said actinic radiation has a wavelength of 436 nm and 365 nm.

12. The process of claim 9, wherein said aqueous developer is a solution selected from the group consisting of alkalis, primary amines, secondary amines, tertiary amines, alcohol amines, quaternary ammonium salts, and mixtures thereof.

13. The process of claim 12, wherein said aqueous developer containing alkali solution is selected from the group consisting of sodium carbonate, potassium carbonate, potassium hydroxide and ammonium hydroxide.

14. An article formed by the process of claim 9, wherein the article is a semiconductor device, a flexible film for electronics, a wire isolation, a wire coating, a wire enamel, or an inked substrate.

15. The article of claim 14, wherein the semiconductor device is an integrated circuit, a light emitting diode, a solar cell, or a transistor.

16. The negative tone photosensitive composition of claim 1, wherein Ar₁ and Ar₂ each independently comprise a member selected from the group consisting of: 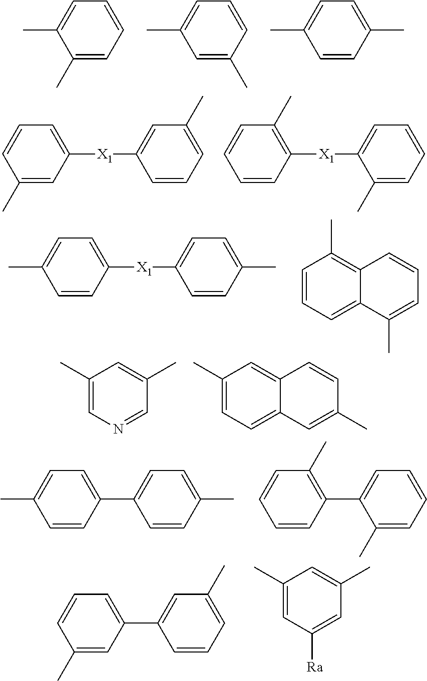
wherein X₁ is —C(O)—C(O)—, —C(O)O—, a C₅-C₇ cyclic aliphatic group, fluorenyl group, —O—X₃—O, —O—C(O)—X₃—C(O)—O—, —C(O)—O—X₃—O—C(O)— or —(CH₂)ₘ—Si(Z)₂—O—Si(Z)₂—(CH₂)ₘ— where X₃ is a unsubstituted or substituted phenyl, diphenyl sulfone, isopropylidene diphenyl, hexafluoroisopropylidene diphenyl and Z is a H or a C₁-C₆ alkyl group and m is an integer from 1 to 6, Ra is each independently a hydrogen atom, an alkoxy, a fluoroalkoxy, a cycloalkyl, a cycloalkoxy, a cycloalkylsulfonyl, an aryloxy, an alkylaryloxy, an arylsulfonyl, or an alkylarylsulfonyl group.

17. The negative tone photosensitive composition of claim 1, wherein Ar₁₁ comprises a member selected from the group consisting of: 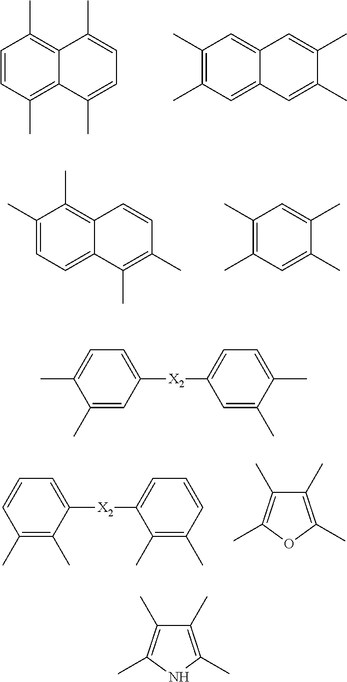
wherein X₂ is —O—, —S—, —C(CF₃)₂—, —C(CH₃)₂—, —CH₂—, —SO₂—, —NHCO—, —C(O)—, —C(O)—C(O)—, —C(O)O—, a C₅-C₇ cyclic aliphatic group, fluorenyl group, —O—X₄—O, —O—C(O)—X₄—C(O)—O—, —C(O)—O—X₄—O—C(O)— or —(CH₂)ₘ—Si(Z)₂—O—Si(Z)₂—(CH₂)ₘ—, X₄ is a unsubstituted or substituted phenyl, diphenyl sulfone, isopropylidene diphenyl, hexafluoroisopropylidene diphenyl; Z is a H or a C₁-C₆ alkyl group and m is an integer from 1 to 6.

18. A polybenzoxazole structure obtained by curing a poly-o-hydroxyamide of claim 1, wherein the polybenzoxazole has the structure 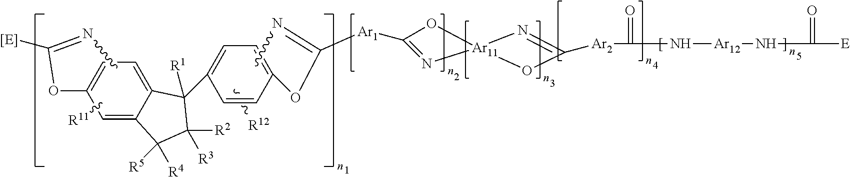
wherein each of R¹, R², R³, R⁴, and R⁵ independently, is a hydrogen atom, a substituted or unsubstituted C₁-C₁₂alkyl, a partially halogen substituted or fully halogen substituted C₁-C₁₂alkyl, a substituted or unsubstituted C₄-C₁₈ cycloalkyl, a substituted or unsubstituted C₆-C₂₂ aryl, or a substituted or unsubstituted C₅-C₂₂ heteroaryl; each of R¹¹ and R¹² is independently a hydrogen atom, a linear or branched C₁-C₄ alkyl, a partially halogen substituted or fully halogen substituted C₁-C₄alkyl, a C₅-C₁₂ cycloalkyl, a C₆-C₁₈ aryl, a C₅-C₁₈ heteroaryl group, a C₁-C₄ alkoxy group or a halogen atom; Ar₁ and Ar₂ are each independently a divalent aromatic, aliphatic, or heterocyclic group, or mixtures thereof; Ar₁₁ and A12 are a divalent aromatic, aliphatic, or heterocyclic group or a siloxane group; E is an end-capping group; n₁ is an integer from 5 to 200; n₃ is an integer from 0 to 200; n₅ is an integer from 0 to 200; n₂ is an integer from 5 to 200 and n₄ is an integer from 0 to 200.

19. The negative tone photosensitive composition of claim 1, wherein the composition is substantially fluorine-free.

20. A photosensitive composition comprising the following components: at least one polymer of claim 1, at least one sensitizer, at least one adhesion promoter, at least one surfactant, at least one solvent, at least one corrosion inhibitor, at least one plasticizer, and at least one additive, wherein each component independently is substantially fluorine-free.
